(19) United States
(12) Patent Application Publication
(10) Pub. No.: US 2025/0048865 A1
(43) Pub. Date: Feb. 6, 2025

(54) DISPLAY DEVICE

(71) Applicant: LG DISPLAY CO., LTD., Seoul (KR)

(72) Inventors: SungHo LEE, Paju-si (KR); HyunTaek LIM, Paju-si (KR); Joohwan HWANG, Paju-si (KR); Huiseong YU, Paju-si (KR); Seokmin HONG, Paju-si (KR); Wooseok NOH, Paju-si (KR); Youngjune GO, Paju-si (KR); Hyejin KIM, Paju-si (KR)

(73) Assignee: LG DISPLAY CO., LTD., Seoul (KR)

(21) Appl. No.: 18/782,705

(22) Filed: Jul. 24, 2024

(30) Foreign Application Priority Data
Aug. 3, 2023 (KR) 10-2023-0101832

(51) Int. Cl. H10K 59/131; H10K 59/122; H10K 59/126; H10K 59/40; H10K 102/00

(52) U.S. Cl. CPC H10K 59/131; H10K 59/122; H10K 59/126; H10K 59/40; H10K 2102/351

(57) ABSTRACT

A display device includes a substrate including a display area in which subpixels are disposed and a non-display area which includes a pad area located in a first direction from the display area; an insulating layer stack located on the substrate, and having an outer side surface; a cathode located on the insulating layer stack, and disposed to extend from the display area to the non-display area; a first inorganic layer located on the cathode, and disposed to extend from the display area to the non-display area; an organic layer located on a part of the first inorganic layer, and having an outer sloped surface; a second inorganic layer located on the organic layer, disposed to extend from the display area to the non-display area, and disposed to extend along the outer sloped surface; and a stopper located on the insulating layer stack, and disposed outside the organic layer.

### CROSS-REFERENCE TO RELATED APPLICATION

This application claims the priority of Korean Patent Application No. 10-2023-0101832 filed on Aug. 3, 2023, which is hereby incorporated by reference in its entirety.

### BACKGROUND

### Field of the Disclosure

The present disclosure relates to a display device.

### Description of the Background

The display panel of a display device may include a display area where an image is displayed and a non-display area where an image is not displayed. Various structures, circuits and lines may be disposed in the non-display area (also referred to as a “bezel”) of the display panel. Due to this fact, it is not easy to reduce the bezel of the display panel.

### SUMMARY

Accordingly, the present disclosure is directed to a display device that substantially obviates one or more of problems due to limitations and disadvantages described above.

More specifically, the present disclosure is to provide a display device having an extremely narrow bezel structure.

The present disclosure is also to provide a display device having an organic layer overflow prevention structure which enables an extremely narrow bezel.

The present disclosure is also to provide a display device including a gate-in-panel circuit structure which enables an extremely narrow bezel.

Further, the present disclosure is to provide a display device having a touch routing structure which enables an extremely narrow bezel.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

To achieve these and other advantages and in accordance with the present disclosure, as embodied and broadly described, a display device includes a substrate including a display area in which a plurality of subpixels are disposed and a non-display area which includes a pad area located in a first direction from the display area; an insulating layer stack located on the substrate, and having an outer side surface in the non-display area; a stopper located on the insulating layer stack; a cathode located on the insulating layer stack, and extending from the display area to a part of the non-display area to overlap at least a portion of a top surface of the stopper; a first inorganic layer located on the cathode, and disposed to extend from the display area to the non-display area; an organic layer located on a part of the first inorganic layer, and having an outer sloped surface; and a second inorganic layer located on the organic layer, disposed to extend from the display area to the non-display area, and disposed to extend along the outer sloped surface of the organic layer.

The stopper may be disposed in the non-display area and may be located outside the organic layer. An outer side surface of the stopper may have a steeper slope than an inner side surface of the stopper.

An end of the common intermediate layer and an end of the cathode may be located on the stopper. The end of the cathode may protrude further outward than an upper layer part of the outer side surface of the stopper and the end of the common intermediate layer.

A display device according to aspects of the present disclosure may include: a substrate; an insulating layer stack on the substrate; a plurality of light emitting elements on the insulating layer stack; an organic layer on the plurality of light emitting elements; and a stopper disposed outside the organic layer.

The stopper may be disposed on an outer side surface of an outermost light emitting element among the plurality of light emitting elements. The stopper may have a thickness thicker than an anode of the outermost light emitting element.

According to various aspects of the present disclosure, it is possible to provide a display device having an extremely narrow bezel structure.

According to various aspects of the present disclosure, it is possible to provide a display device having an organic layer overflow prevention structure which enables an extremely narrow bezel.

According to various aspects of the present disclosure, it is possible to provide a display device including a gate-in-panel circuit structure which enables an extremely narrow bezel.

According to various aspects of the present disclosure, it is possible to provide a display device having a touch routing structure which enables an extremely narrow bezel.

According to various aspects of the present disclosure, by having an extremely narrow bezel structure, it is possible to reduce the weight of a display device.

It is to be understood that both the foregoing general description and the following detailed description are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain the principle of the disclosure.

In the drawings:

FIG. 1 is a system configuration diagram of a display device according to aspects of the present disclosure;

FIG. 2 shows a display panel according to aspects of the present disclosure;

FIG. 3 shows a substrate of a display panel according to aspects of the present disclosure;

FIGS. 4 and 5 are cross-sectional views of display panels according to aspects of the present disclosure;

FIG. 6 is a cross-sectional view of the outer area of a display panel according to aspects of the present disclosure;

FIG. 7 is a cross-sectional view of a display panel according to aspects of the present disclosure;

FIG. 8 is a cross-sectional view of a display panel according to aspects of the present disclosure;

FIG. 9 is a plan view showing a touch sensor included in a display panel according to aspects of the present disclosure;

FIG. 10 shows in detail as an example a partial area of a touch sensor included in a display panel according to aspects of the present disclosure.

FIG. 11 shows a substrate and an encapsulation layer of a display panel according to aspects of the present disclosure.

FIGS. 12 and 13 are cross-sectional views of display panels according to aspects of the present disclosure;

FIG. 14 shows a gate driving circuit of a display device according to aspects of the present disclosure;

FIG. 15 shows the vertical structure of a display panel according to aspects of the present disclosure when a gate-in-panel circuit is disposed over the entirety of the display area of the display panel;

FIG. 16 is a cross-sectional view of the display area of a display panel according to aspects of the present disclosure;

FIGS. 17 and 18 show the vertical structure and the planar structure of a display panel according to aspects of the present disclosure when a gate-in-panel circuit is disposed in a part of the display area of the display panel;

FIG. 19 is a plan view of a partial area of a display panel according to aspects of the present disclosure;

FIG. 20 shows the correspondence relationship between subpixel circuits and light emitting elements in a display panel according to aspects of the present disclosure; and

FIG. 21 is a cross-sectional view of a display panel according to aspects of the present disclosure.

### DETAILED DESCRIPTION

In the following description of examples or aspects of the present disclosure, reference will be made to the accompanying drawings in which it is shown by way of illustration specific examples or aspects that may be implemented, and in which the same reference numerals and signs may be used to designate the same or like components even when they are shown in different accompanying drawings from one another. Further, in the following description of examples or aspects of the present disclosure, detailed descriptions of well-known functions and components incorporated herein will be omitted when it is determined that the description may make the subject matter in some aspects of the present disclosure rather unclear. The terms such as “including,” “having,” “containing,” “constituting,” “make up of” and “formed of” used herein are generally intended to allow other components to be added unless the terms are used with the term “only.” As used herein, singular forms are intended to include plural forms unless the context clearly indicates otherwise.

Terms, such as “first”, “second”, “A,” “B,” “(A)” or “(B)” may be used herein to describe elements of the present disclosure. Each of these terms is not used to define essence, order, sequence, number of elements, etc., but is used merely to distinguish the corresponding element from other elements.

When it is mentioned that a first element “is connected or coupled to,” “contacts or overlaps,” etc. a second element, it should be interpreted that, not only may the first element “be directly connected or coupled to” or “directly contact or overlap” the second element, but a third element may also be “interposed” between the first and second elements, or the first and second elements may “be connected or coupled to,” “contact or overlap,” etc. each other via a fourth element. Here, the second element may be included in at least one of two or more elements that “are connected or coupled to,” “contact or overlap,” etc. each other.

When time relative terms, such as “after,” “subsequent to,” “next,” “before” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes, etc. are mentioned, it should be considered that numerical values for elements or features, or corresponding information (e. g., level, range, etc.) include a tolerance or error range that may be caused by various factors (e. g., process factors, internal or external impact, noise, etc.) even when a relevant description is not specified. Further, the term “may” fully encompass all the meanings of the term “may.”

Hereinafter, various aspects of the present disclosure will be described in detail with reference to accompanying drawings.

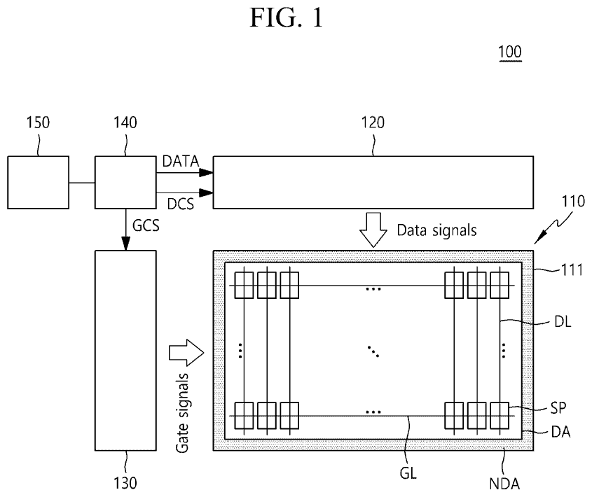

FIG. 1 is a system configuration diagram of a display device 100 according to aspects of the present disclosure.

Referring to FIG. 1, the display device 100 according to the aspects of the present disclosure may include a display panel 110 and a display driving circuit as components for displaying an image. The display driving circuit as a circuit for driving the display panel 110 may include a data driving circuit 120, a gate driving circuit 130 and a display controller 140.

The display panel 110 may include a substrate 111 and a plurality of subpixels SP which are disposed on the substrate 111.

The substrate 111 of the display panel 110 may include a display area DA capable of displaying an image and a non-display area NDA which is located outside the display area DA.

The plurality of subpixels SP for displaying an image may be disposed in the display area DA, and the non-display area NDA may include a pad area located in a first direction from the display area DA.

In the display panel 110 according to the aspects of the present disclosure, the non-display area NDA may be very small. In the present specification, the non-display area NDA may also be referred to as a “bezel.”

For example, the non-display area NDA may include a first non-display area which is located outside the display area DA in the first direction, a second non-display area which is located outside the display area DA in a second direction intersecting the first direction, a third non-display area which is located outside the display area DA in a direction opposite to the first direction, and a fourth non-display area which is located outside the display area DA in a direction opposite to the second direction. One or two among the first to fourth non-display areas may include the pad area to which the data driving circuit 120 is connected or bonded. Two or three among the first to fourth non-display areas in which the pad area is not included may be very small in size.

For another example, a boundary area between the display area DA and the non-display area NDA may be bent, and thus, the non-display area NDA may be located under the display area DA. In this case, when a user looks at the display device 100 from the front, little or no non-display area NDA may be visible to the user.

Various types of signal lines for driving the plurality of subpixels SP may be disposed on the substrate 111 of the display panel 110.

The display device 100 according to the aspects of the present disclosure may be a liquid crystal display device or the like, or may be a self-emissive display device in which the display panel 110 self-emits light. When the display device 100 according to the aspects of the present disclosure is a self-emissive display device, each of the plurality of subpixels SP may include a light emitting element.

For example, the display device 100 according to the aspects of the present disclosure may be an organic light emitting display device in which a light emitting element is implemented using an organic light emitting diode (OLED). For another example, the display device 100 according to the aspects of the present disclosure may be an inorganic light emitting display device in which a light emitting element is implemented using an inorganic-based light emitting diode. For still another example, the display device 100 according to the aspects of the present disclosure may be a quantum dot display device in which a light emitting element is implemented using quantum dots as semiconductor crystals which self-emit light.

The structure of each of the plurality of subpixels SP may vary depending on the type of the display device 100. For example, when the display device 100 is a self-emissive display device in which each subpixel SP self-emits light, each subpixel SP may include a self-emissive light emitting element, at least one transistor and at least one capacitor.

For example, the various types of signal lines may include a plurality of data lines DL which transfer data signals (also referred to as data voltages or image signals) and a plurality of gate lines GL which transfer gate signals (also referred to as scan signals).

For example, the plurality of data lines DL and the plurality of gate lines GL may intersect each other. Each of the plurality of data lines DL may be disposed to extend in a first direction, and each of the plurality of gate lines GL may be disposed to extend in a second direction. The first direction may be a column direction, and the second direction may be a row direction. Alternatively, the first direction may be a row direction, and the second direction may be a column direction. Hereunder, for the sake of convenience in explanation, it will be described as an example that each of the plurality of data lines DL is disposed in a column direction and each of the plurality of gate lines GL is disposed in a row direction.

The data driving circuit 120 as a circuit for driving the plurality of data lines DL may output data signals to the plurality of data lines DL.

The data driving circuit 120 may receive image data DATA of a digital type from the display controller 140, may convert the received image data DATA into data signals of an analog type, and may output the data signals to the plurality of data lines DL.

For example, the data driving circuit 120 may be connected to the display panel 110 in a tape automated bonding (TAB) method, may be connected to bonding pads of the display panel 110 in a chip-on-glass (COG) or chip-on-panel (COP) method, or may be connected to the display panel 110 by being implemented in a chip-on-film (COF) method.

The data driving circuit 120 may be connected to one side (e.g., the upper side or the lower side) of the display panel 110. Unlike this, depending on a driving method, a panel design method, etc., the data driving circuit 120 may be connected to both sides (e.g., the upper side and the lower side) of the display panel 110, or may be connected to at least two sides of the four sides of the display panel 110.

The data driving circuit 120 may be connected to the outside of the display area DA of the display panel 110, but unlike this, may be disposed in the display area DA of the display panel 110.

The gate driving circuit 130 as a circuit for driving the plurality gate lines GL may output gate signals to the plurality of gate lines GL.

The gate driving circuit 130 may be supplied with a first gate voltage corresponding to a turn-on level voltage and a second gate voltage corresponding to a turn-off level voltage along with various gate driving control signals GCS, may generate gate signals, and may supply the generated gate signals to the plurality of gate lines GL.

In the display device 100 according to the aspects of the present disclosure, the gate driving circuit 130 may be embedded in the display panel 110 in a gate-in-panel (GIP) type. When the gate driving circuit 130 is a gate-in-panel (GIP) type, the gate driving circuit 130 may be formed on the substrate 111 of the display panel 110 during the manufacturing process of the display panel 110.

In the display device 100 according to the aspects of the present disclosure, the gate driving circuit 130 may be disposed in the display area DA of the display panel 110. For example, the gate driving circuit 130 may be disposed in a first partial area in the display area DA (e.g., a left area or a right area in the display area DA). For another example, the gate driving circuit 130 may be disposed in a first partial area in the display area DA (e.g., a left area or a right area in the display area DA) and a second partial area in the display area DA (e.g., the right area or the left area in the display area DA).

In the present disclosure, the gate driving circuit 130 which is embedded in the display panel 110 in a gate-in-panel (GIP) type is referred to as a “gate-in-panel circuit.”

The display controller 140 as a device for controlling the data driving circuit 120 and the gate driving circuit 130 may control driving timing for the plurality of data lines DL and driving timing for the plurality of gate lines GL.

The display controller 140 may supply a data driving control signal DCS to the data driving circuit 120 to control the data driving circuit 120, and may supply a gate driving control signal GCS to the gate driving circuit 130 to control the gate driving circuit 130.

The display controller 140 may receive input image data from a host system 150, and may supply image data DATA to the data driving circuit 120 on the basis of the input image data.

The display controller 140 may be implemented as a component separate from the data driving circuit 120, or may be implemented as an integrated circuit by being integrated with the data driving circuit 120.

The display controller 140 may be a timing controller which is used in general display technology, may be a control device which includes a timing controller and is capable of further performing other control functions, may be a control device which is different from a timing controller, or may be a circuit in a control device. The display controller 140 may be implemented by various circuits or electronic parts such as an integrated circuit (IC), a field programmable gate array (FPGA), an application specific integrated circuit (ASIC) and a processor.

The display controller 140 may be mounted on a printed circuit board, a flexible printed circuit or the like, and may be electrically connected to the data driving circuit 120 and the gate driving circuit 130 through the printed circuit board, the flexible printed circuit or the like.

The display controller 140 may transmit and receive signals to and from the data driving circuit 120 according to at least one predetermined interface. For example, the interface may include a low voltage differential signaling (LVDS) interface, an EPI (embedded clock point-point interface), a serial peripheral interface (SPI), etc.

To further provide a touch sensing function as well as an image display function, the display device 100 according to the aspects of the present disclosure may include a touch sensor and a touch sensing circuit which, by sensing the touch sensor, detects whether a touch event has occurred by a touch object such as a finger or a pen or detects a touch position.

The touch sensing circuit may include a touch driving circuit which generates and outputs touch sensing data by driving and sensing the touch sensor, and a touch controller which is able to detect the occurrence of a touch event or detect a touch position using the touch sensing data.

The touch sensor may include a plurality of touch electrodes. The touch sensor may further include a plurality of touch lines for electrically connecting the plurality of touch electrodes and the touch driving circuit.

The touch sensor may exist in the form of a touch panel outside the display panel 110, or may exist inside the display panel 110. In the case where the touch sensor exists in the form of a touch panel outside the display panel 110, the touch sensor may be referred to as an external type. When the touch sensor is an external type, the touch panel and the display panel 110 may be separately manufactured and be coupled during an assembly process. The external type touch panel may include a substrate for a touch panel and a plurality of touch electrodes on the substrate for a touch panel.

When the touch sensor exists inside the display panel 110, the touch sensor may be formed on the substrate 111 together with signal lines and electrodes related with display driving during the process of manufacturing the display panel 110.

The touch driving circuit may supply a touch driving signal to at least one of the plurality of touch electrodes, and may generate touch sensing data by sensing at least one of the plurality of touch electrodes.

The touch sensing circuit may perform touch sensing in a self-capacitance sensing method or a mutual-capacitance sensing method.

In the case where the touch sensing circuit performs touch sensing in the self-capacitance sensing method, the touch sensing circuit may perform touch sensing on the basis of the capacitance between each touch electrode and a touch object (e.g., a finger, a pen, etc.). According to the self-capacitance sensing method, each of the plurality of touch electrodes may serve as both a driving touch electrode and a sensing touch electrode. The touch driving circuit may drive all or some of the plurality of touch electrodes, and may sense all or some of the plurality of touch electrodes.

In the case where the touch sensing circuit performs touch sensing in the mutual-capacitance sensing method, the touch sensing circuit may perform touch sensing on the basis of the capacitance between touch electrodes. According to the mutual-capacitance sensing method, the plurality of touch electrodes are divided into driving touch electrodes and sensing touch electrodes. The touch driving circuit may drive the driving touch electrodes and sense the sensing touch electrodes.

The touch driving circuit and the touch controller included in the touch sensing circuit may be implemented as separate devices or may be implemented as a single device. Further, the touch driving circuit and the data driving circuit 120 may be implemented as separate devices or may be implemented as a single device.

The display device 100 may further include a power supply circuit which supplies various types of power to the display driving circuit and/or the touch sensing circuit.

The display device 100 according to the aspects of the present disclosure may be a mobile terminal such as a smart phone and a tablet or a monitor or a television (TV) of various sizes. However, the display device 100 according to the aspects of the present disclosure is not limited thereto, and may be a display of various types and various sizes capable of displaying information or an image.

The display device 100 according to the aspects of the present disclosure may further include an electronic device such as a camera (an image sensor) and a sensing sensor. For example, the sensing sensor may be a sensor which detects an object or a human body by receiving light such as infrared light, ultrasonic light and ultraviolet light.

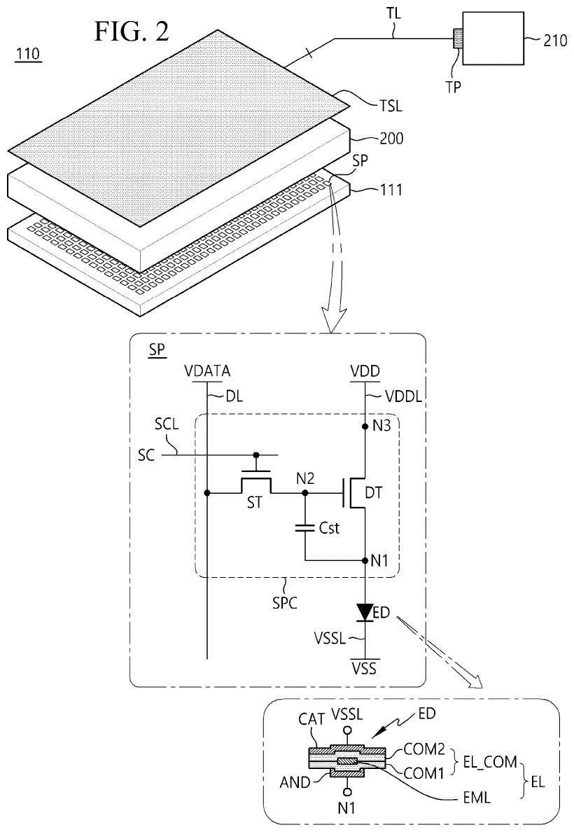

FIG. 2 shows a display panel 110 according to aspects of the present disclosure.

Referring to FIG. 2, the display panel 110 may include a substrate 111 on which a plurality of subpixels SP are disposed, and an encapsulation layer 200 on the substrate 111. The encapsulation layer 200 may also be referred to as an encapsulation substrate or an encapsulation part.

Referring to FIG. 2, in the case where the display device 100 according to the aspects of the present disclosure is a self-emissive display device, each of the plurality of subpixels SP which are disposed on the substrate 111 may include a light emitting element ED and a subpixel circuit SPC for driving the light emitting element ED.

Referring to FIG. 2, the subpixel circuit SPC may include a plurality of pixel driving transistors for driving the light emitting element ED and at least one capacitor. In the present disclosure, the subpixel circuit SPC may drive the light emitting element ED by supplying driving current to the light emitting element ED at predetermined timing. The light emitting element ED may be driven by the driving current to emit light.

The plurality of pixel driving transistors may include a driving transistor DT for driving the light emitting element ED and a scan transistor ST which is turned on or off according to a scan signal SC.

The driving transistor DT may supply driving current to the light emitting element ED.

The scan transistor ST may be configured to control the electrical state of a corresponding node in the subpixel circuit SPC or control the state or operation of the driving transistor DT.

The at least one capacitor may include a storage capacitor Cst for maintaining a constant voltage during a frame.

To drive the subpixel SP, a data signal VDATA as an image signal, the scan signal SC as a gate signal, etc. may be applied to the subpixel SP. Further, to drive the subpixel SP, common pixel driving voltages including a first common driving voltage VDD and a second common driving voltage VSS may be applied to the subpixel SP.

The light emitting element ED may include an anode AND, a light emitting element intermediate layer EL and a cathode CAT. The light emitting element intermediate layer EL may be disposed between the anode AND and the cathode CAT.

In the case where the light emitting element ED is an organic light emitting element, the light emitting element intermediate layer EL may include a light emitting layer EML, a first common intermediate layer COM1 between the anode AND and the light emitting layer EML, and a second common intermediate layer COM2 between the light emitting layer EML and the cathode CAT. The light emitting layer EML may be disposed in each subpixel SP. In comparison with this, the first common intermediate layer COM1 and the second common intermediate layer COM2 may be disposed in common across a plurality of subpixels SP. The light emitting layer EML may be disposed in each light emitting area, and the first common intermediate layer COM1 and the second common intermediate layer COM2 may be disposed in common across a plurality of light emitting areas and non-light emitting areas. The first common intermediate layer COM1 and the second common intermediate layer COM2 are collectively referred to as a common intermediate layer EL_COM.

For example, the first common intermediate layer COM1 may include a hole injection layer (HIL) and a hole transfer layer (HTL). The second common intermediate layer COM2 may include an electron transfer layer (ETL) and an electron injection layer (EIL). The hole injection layer may inject holes from the anode AND into the hole transfer layer, the hole transfer layer may transfer holes to the light emitting layer EML, the electron injection layer may inject electrons from the cathode ACT into the electron transfer layer, and the electron transfer layer may transfer electrons to the light emitting layer EML.

For example, the cathode CAT may be electrically connected to a second common driving voltage line VSSL. The second common driving voltage VSS, which is a type of common pixel driving voltage, may be applied to the cathode CAT through the second common driving voltage line VSSL. The anode AND may be electrically connected to a first node N1 of the driving transistor DT of each subpixel SP. In the present disclosure, the second common driving voltage VSS may also be referred to as a base voltage VSS, and the second common driving voltage line VSSL may also be referred to as a base voltage line VSSL.

For example, the anode AND may be a pixel electrode which is disposed in each subpixel SP, and the cathode CAT may be a common electrode which is disposed in common in a plurality of subpixels SP. For another example, the cathode CAT may be a pixel electrode which is disposed in each subpixel SP, and the anode AND may be a common electrode which is disposed in common in a plurality of subpixels SP. Hereinbelow, for the sake of convenience in explanation, it is assumed that the anode AND is a pixel electrode and the cathode CAT is a common electrode.

Each light emitting element ED may be composed of overlapping portions of the anode AND, the light emitting element intermediate layer EL and the cathode CAT. A predetermined light emitting area may be formed by each light emitting element ED. For example, the light emitting area of each light emitting element ED may include an area where the anode AND, the light emitting element intermediate layer EL and the cathode CAT overlap.

For example, the light emitting element ED may be an organic light emitting diode (OLED), an inorganic-based light emitting diode (LED) or a quantum dot light emitting element. For example, when the light emitting element ED is an organic light emitting diode (OLED), the light emitting element intermediate layer EL in the light emitting element ED may include a light emitting element intermediate layer EL which includes an organic material.

The driving transistor DT may be a driving transistor for supplying driving current to the light emitting element ED. The driving transistor DT may be connected between a first common driving voltage line VDDL and the light emitting element ED.

The driving transistor DT may include the first node N1 which is electrically connected to the light emitting element ED, a second node N2 to which a data signal VDATA may be applied, and a third node N3 to which the driving voltage VDD is applied from the first common driving voltage line VDDL.

In the driving transistor DT, the second node N2 may be a gate node, the first node N1 may be a source node or a drain node, and the third node N3 may be a drain node or a source node. Hereinbelow, for the sake of convenience in explanation, it will be described as an example that, in the driving transistor DT, the second node N2 is a gate node, the first node N1 is a source node and the third node N3 is a drain node.

The scan transistor ST included in the subpixel circuit SPC illustrated in FIG. 2 may be a switching transistor for transferring the data signal VDATA as an image signal to the second node N2 which is the gate node of the driving transistor DT.

The scan transistor ST may be on-off controlled by the scan signal SC as a gate signal applied through a scan line SCL which is a type of gate line GL, and thus, may control the electrical connection between the second node N2 of the driving transistor DT and a data line DL. The drain electrode or the source electrode of the scan transistor ST may be electrically connected to the data line DL, the source electrode or the drain electrode of the scan transistor ST may be electrically connected to the second node N2 of the driving transistor DT, and the gate electrode of the scan transistor ST may be electrically connected to the scan line SCL.

The storage capacitor Cst may be electrically connected between the first node N1 and the second node N2 of the driving transistor DT. The storage capacitor Cst may include a first capacitor electrode which is electrically connected to the first node N1 of the driving transistor DT or corresponds to the first node N1 of the driving transistor DT, and a second capacitor electrode which is electrically connected to the second node N2 of the driving transistor DT or corresponds to the second node N2 of the driving transistor DT.

The storage capacitor Cst may be not a parasitic capacitor (e.g., Cgs or Cgd) which is an internal capacitor likely to exist between the first node N1 and the second node N2 of the driving transistor DT but an external capacitor which is intentionally designed outside the driving transistor DT.

Each of the driving transistor DT and the scan transistor ST may be an n-type transistor or a p-type transistor.

The display panel 110 may have a top emission structure or a bottom emission structure.

When the display panel 110 has the top emission structure, at least a portion of the subpixel circuit SPC may overlap at least a portion of the light emitting element ED in a vertical direction. Unlike this, when the display panel 110 has the bottom emission structure, the subpixel circuit SPC may not overlap the light emitting element ED in the vertical direction.

As illustrated in FIG. 2, the subpixel circuit SPC may have a 2T (transistor) 1C (capacitor) structure including two transistors DT and ST and one capacitor Cst. As the case may be, the subpixel circuit SPC may further include at least one transistor and may further include at least one capacitor.

For example, the subpixel circuit SPC may have an 8T1C structure including eight transistors and one capacitor. For another example, the subpixel circuit SPC may have a 6T2C structure including six transistors and two capacitors. For still another example, the subpixel circuit SPC may have a 7T1C structure including seven transistors and one capacitor.

The types and number of gate signals supplied to the subpixel SP and the types and number of gate lines may vary depending on the structure of the subpixel circuit SPC.

Further, the types and number of common pixel driving voltages supplied to the subpixel SP may vary depending on the structure of the subpixel circuit SPC.

Because circuit elements (in particular, the light emitting element ED implemented by an organic light emitting diode (OLED) including an organic material) in each subpixel SP are vulnerable to external moisture or oxygen, the encapsulation layer 200 for preventing external moisture or oxygen from penetrating into the circuit elements (in particular, the light emitting element ED) may be disposed. The encapsulation layer 200 may be configured in various shapes to prevent light emitting elements ED from contacting moisture or oxygen.

Referring to FIG. 2, to sense a user's touch, the display device 100 according to the aspects of the present disclosure may further include a touch sensor layer TSL which includes a plurality of sensor electrodes, and a touch sensing circuit 210 which is configured to sense the plurality of sensor electrodes and thereby determine whether a touch event has occurred or touch coordinates.

The touch sensor layer TSL may be embedded in the display panel 110. For example, the touch sensor layer TSL may be disposed on the encapsulation layer 200 in the display panel 110.

The display panel 110 not only includes the touch sensor layer TSL, but also may include a plurality of touch pads TP to which the touch sensing circuit 210 is electrically connected and a plurality of touch routing lines TL for electrically connecting the plurality of sensor electrodes included in the touch sensor layer TSL and the plurality of touch pad TP to which the touch sensing circuit 210 is connected.

Meanwhile, the display device 100 according to the aspect of the present disclosure may have an extremely narrow bezel structure in which the non-display area NDA of the display panel 110 is very small or is almost absent. Hereinafter, the extremely narrow bezel structure of the display panel 110 of the display device 100 according to the aspect of the present disclosure will be described.

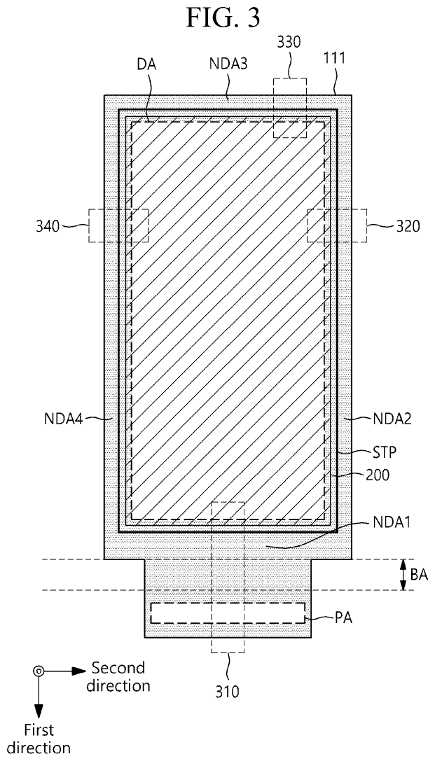

FIG. 3 shows a substrate 111 of a display panel 110 according to aspects of the present disclosure.

Referring to FIG. 3, the substrate 111 of the display panel 110 according to the aspects of the present disclosure may include a display area DA where an image may be displayed and a non-display area NDA where an image is not displayed.

Referring to FIG. 3, the non-display area NDA may include a first non-display area NDA1 which is located in a first direction from the display area DA, a second non-display area NDA2 which is located in a second direction from the display area DA, a third non-display area NDA3 which is located in a direction opposite to the first direction from the display area DA, and a fourth non-display area NDA4 which is located in a direction opposite to the second direction from the display area DA. For example, the first direction may be a column direction (the Y-axis direction), and the second direction intersecting the first direction may be a row direction (the X-axis direction).

Referring to FIG. 3, the first non-display area NDA1 may include a pad area PA in which a plurality of pads are disposed.

In the pad area PA, the plurality of pads to which driving circuits are electrically connected may be disposed. A plurality of driving circuits or a printed circuit board may be electrically connected. For example, the plurality of pads may include a plurality of display pads and a plurality of touch pads. A plurality of data lines DL, a first common driving voltage line VDDL and a second common driving voltage line VSSL may be electrically connected to the plurality of display pads. A plurality of touch routing lines TL may be electrically connected to the plurality of touch pads.

Referring to FIG. 3, the first non-display area NDA1 may further include a bending area BA. In this case, the substrate 111 may be a flexible substrate. As the case may be, the first non-display area NDA1 may not include the bending area BA.

Referring to FIG. 3, the display panel 110 may further include a ground line which is disposed in the non-display area NDA of the substrate 111. The ground line may be disposed from one point of the pad area PA to another point of the pad area PA via the second non-display area NDA2, the third non-display area NDA3 and the fourth non-display area NDA4.

Referring to FIG. 3, in the display panel 110 according to the aspects of the present disclosure, an encapsulation layer 200 may have a structure in which an inorganic layer and an organic layer are stacked. In this case, the edge of the encapsulation layer 200 may be regarded as the edge of the organic layer.

Referring to FIG. 3, the display panel 110 according to the aspects of the present disclosure may include a stopper STP as an organic layer overflow prevention structure for preventing overflow of the organic layer included in the encapsulation layer 200.

Referring to FIG. 3, in the display panel 110 according to the aspects of the present disclosure, the stopper STP may be disposed in the non-display area NDA, and may be disposed in the shape of a ring which surrounds the periphery of the organic layer.

Referring to FIG. 3, the stopper STP may be located between the display area DA and the pad area PA.

Referring to FIG. 3, in the display panel 110 according to the aspects of the present disclosure, the stopper STP may be disposed in the non-display area NDA. In this way, even though the stopper STP is disposed in the non-display area NDA, the size of the non-display area NDA may not increase due to the presence of the stopper STP.

In the display panel 110 according to the aspects of the present disclosure, the stopper STP may have a structure which rather reduces the non-display area NDA while serving to prevent overflow of the organic layer.

Hereinafter, the stopper STP, which serves as not only an organic layer overflow prevention structure capable of preventing overflow of the organic layer included in the encapsulation layer 200 but also one of extremely narrow bezel structures capable of reducing a bezel size, will be described in more detail.

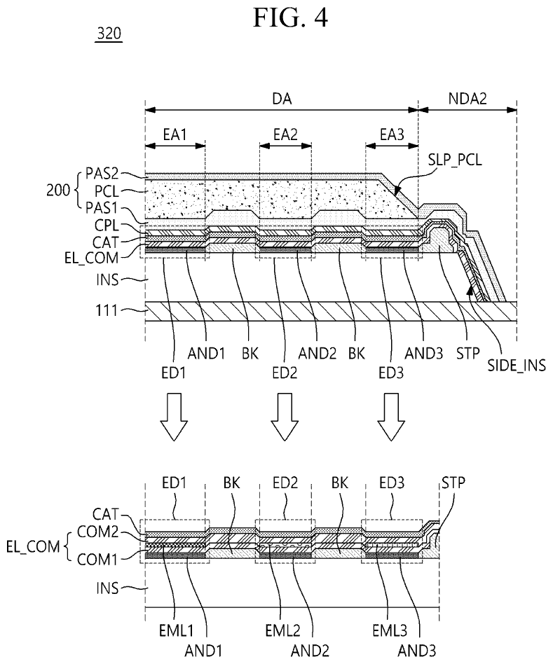

FIG. 4 is a cross-sectional view of a display panel 110 according to aspects of the present disclosure. FIG. 4 is a cross-sectional view of the area 320 including the second non-display area NDA2 in FIG. 3. In FIG. 3, the vertical structure of each of the area 330 including the third non-display area NDA3 and the area 340 including the fourth non-display area NDA4 may be the same as the vertical structure of the area 320 including the second non-display area NDA2.

Referring to FIG. 4, the display panel 110 according to the aspects of the present disclosure may include the substrate 111, an insulating layer stack INS on the substrate 111, a plurality of light emitting elements ED1, ED2 and ED3 on the insulating layer stack INS, an organic layer PCL on the plurality of light emitting elements ED1, ED2 and ED3, and a stopper STP which is disposed outside the organic layer PCL.

The substrate 111 may include the display area DA and the non-display area NDA, and the non-display area NDA may include the second non-display area NDA2 which is located in the second direction from the display area DA.

The insulating layer stack INS may include a plurality of insulating layers located between the substrate 111 and the plurality of light emitting elements ED1, ED2 and ED3.

The insulating layer stack INS may be located on the substrate 111, and may have an outer side surface SIDE_INS in the non-display area NDA. The insulating layer stack INS may include a plurality of insulating layers.

The insulating layer stack INS may include a plurality of insulating layers which are necessary to form transistors. The insulating layer stack INS may include an organic insulating layer stack including at least one organic insulating layer and an inorganic insulating layer stack including at least one inorganic insulating layer. For example, the organic insulating layer stack may include at least one planarization layer, and the inorganic insulating layer stack may include at least one buffer layer, at least one gate insulating layer or at least one interlayer insulating layer.

To form the plurality of light emitting elements ED1, ED2 and ED3 on the insulating layer stack INS, the display panel 110 may include a bank BK which is located on the insulating layer stack INS as a subpixel defining layer for dividing a plurality of light emitting areas EA1, EA2 and EA3 and has a plurality of openings, a plurality of anodes AND1, AND2 and AND3 which are located on the insulating layer stack INS and overlap the plurality of openings of the bank BK, a plurality of light emitting layers EML1, EML2 and EML3 which are located on the plurality of anodes AND1, AND2 and AND3, and a cathode CAT which is located on the plurality of light emitting layers EML1, EML2 and EML3 and is disposed to extend from the display area DA to a part of the non-display area NDA.

The plurality of light emitting elements ED1, ED2 and ED3 may be configured as the plurality of anodes AND1, AND2 and AND3, the plurality of light emitting layers EML1, EML2 and EML3 and the cathode CAT overlap.

Referring to FIG. 4, the insulating layer stack INS may include the plurality of insulating layers which are disposed between the substrate 111 and the plurality of anodes AND1, AND2 and AND3.

Referring to FIG. 4, the display panel 110 according to the aspects of the present disclosure may include the stopper STP which is not only an organic layer overflow prevention structure but also one of extremely narrow bezel structures.

Referring to FIG. 4, the stopper STP may be located on the insulating layer stack INS, may be disposed in the non-display area NDA, and may be located outside the organic layer PCL. The cathode CAT may be located on the insulating layer stack INS, and may extend from the display area DA to the part of the non-display area NDA to overlap at least a portion of the top surface of the stopper STP.

In the display panel 110 according to the aspects of the present disclosure, the stopper STP may be disposed outside a third light emitting element ED3, which is an outermost light emitting element ED among the plurality of light emitting elements ED1, ED2 and ED3. The stopper STP may be disposed on the outer side surface of the third light emitting element ED3, which is the outermost light emitting element ED among the plurality of light emitting elements ED1, ED2 and ED3. The stopper STP may be disposed outside the bank BK.

The stopper STP may include an organic material.

The stopper STP may have a thickness thicker than the anode AND3 of the third light emitting element ED3 which is the outermost light emitting element ED. For example, the stopper STP may have a thickness thicker than the sum of the thicknesses of the anode AND3, a light emitting element intermediate layer EL and the cathode CAT of the third light emitting element ED3 which is the outermost light emitting element ED. The light emitting element intermediate layer EL of the third light emitting element ED3 which is the outermost light emitting element ED may include a first common intermediate layer COM1, a third light emitting layer EML3 and a second common intermediate layer COM2.

For example, the uppermost surface of the stopper STP may be located to be higher than the top surface of the cathode CAT in the light emitting areas EA1, EA2 and EA3. Accordingly, the cathode CAT may be disposed along the inner side surface of the stopper STP and extend upward to the top of the stopper STP.

Referring to FIG. 4, for example, the plurality of light emitting elements ED1, ED2 and ED3 may include a first light emitting element ED1 which is located in a first light emitting area EA1, a second light emitting element ED2 which is located in a second light emitting area EA2 and the third light emitting element ED3 which is located in a third light emitting area EA3.

The first light emitting element ED1 may include a first anode AND1, a first light emitting element intermediate layer EL and the cathode CAT, and the first light emitting element intermediate layer EL of the first light emitting element ED1 may include the first common intermediate layer COM1, a first light emitting layer EML1 and the second common intermediate layer COM2.

The second light emitting element ED2 may include a second anode AND2, a second light emitting element intermediate layer EL and the cathode CAT, and the second light emitting element intermediate layer EL of the second light emitting element ED2 may include the first common intermediate layer COM1, a second light emitting layer EML2 and the second common intermediate layer COM2.

The third light emitting element ED3 may include a third anode AND3, a third light emitting element intermediate layer EL and the cathode CAT, and the third light emitting element intermediate layer EL of the third light emitting element ED3 may include the first common intermediate layer COM1, the third light emitting layer EML3 and the second common intermediate layer COM2.

The first anode AND1, the second anode AND2 and the third anode AND3 may be disposed in the first light emitting area EA1, the second light emitting area EA2 and the third light emitting area EA3, respectively.

The first light emitting layer EML1, the second light emitting layer EML2 and the third light emitting layer EML3 may be disposed in the first light emitting area EA1, the second light emitting area EA2 and the third light emitting area EA3, respectively.

The first common intermediate layer COM1, the second common intermediate layer COM2 and the cathode CAT may be disposed over the entire display area DA, and may extend from the display area DA to at least a part of the non-display area NDA. In the aspect of the present disclosure, the first common intermediate layer COM1 and the second common intermediate layer COM2 may also be collectively referred to as a common intermediate layer EL_COM.

Referring to FIG. 4, the display panel 110 according to the aspects of the present disclosure may include a first inorganic layer PAS1, the organic layer PCL and a second inorganic layer PAS2.

Referring to FIG. 4, the first inorganic layer PAS1 may be located on the cathode CAT, and may be disposed to extend from the display area DA to the non-display area NDA including the second non-display area NDA2.

Referring to FIG. 4, the organic layer PCL may be located on a part of the first inorganic layer PAS1, and may have an outer sloped surface SLP_PCL.

Referring to FIG. 4, the second inorganic layer PAS2 may be located on the organic layer PCL, may be disposed to extend from the display area DA to the non-display area NDA, and may be disposed to extend along the outer sloped surface SLP_PCL of the organic layer PCL.

The first inorganic layer PAS1, the organic layer PCL and the second inorganic layer PAS2 may be layers which constitute an encapsulation layer 200.

The stopper STP may be located on the insulating layer stack INS, and may be disposed outside the organic layer PCL.

The first inorganic layer PAS1 may extend along the top and outside of the stopper STP to the outer side surface SIDE_INS of the insulating layer stack INS.

The second inorganic layer PAS2 may extend to the outside of the outer sloped surface SLP_PCL of the organic layer PCL, and may be located on the first inorganic layer PAS1 which extends along the top and outside of the stopper STP to the outer side surface SIDE_INS of the insulating layer stack INS.

The bank BK may be located on the insulating layer stack INS, and may have first to third openings. The first to third openings may correspond to the first to third light emitting areas EA1, EA2 and EA3.

The first to third anodes AND1, AND2 and AND3 may be located on the insulating layer stack INS, and may overlap the first to third openings, respectively, of the bank BK.

The first common intermediate layer COM1 may be disposed in common on the first to third anodes AND1, AND2 and AND3, and may also be disposed on the bank BK.

The first to third light emitting layers EML1, EML2 and EML3 may be located on the first common intermediate layer COM1, and may overlap the first to third anodes AND1, AND2 and AND3. The first to third light emitting layers EML1, EML2 and EML3 may correspond to the first to third light emitting areas EA1, EA2 and EA3.

The second common intermediate layer COM2 may be disposed in common on the first to third light emitting layers EML1, EML2 and EML3, and may also be disposed on the bank BK.

The common intermediate layer EL_COM including the first common intermediate layer COM1 and the second common intermediate layer COM2 may exist on the bank BK, and may be disposed over the entire display area DA. The common intermediate layer EL_COM including the first common intermediate layer COM1 and the second common intermediate layer COM2 may include an organic material.

The cathode CAT may be located on the second common intermediate layer COM2.

Referring to FIG. 4, the common intermediate layer EL_COM and the cathode CAT may extend to the top of the stopper STP to overlap at least a portion of the stopper STP.

For example, the common intermediate layer EL_COM and the cathode CAT may extend to the top and the outer side surface of the stopper STP. When the common intermediate layer EL_COM and the cathode CAT extend farther, the common intermediate layer EL_COM and the cathode CAT may pass over the top and the outer side surface of the stopper STP and extend to the outer side surface SIDE_INS of the insulating layer stack INS.

Referring to FIG. 4, the display panel 110 may further include a capping layer CPL which is located between the cathode CAT and the first inorganic layer PAS1 and is disposed to extend from the display area DA to the non-display area NDA. The capping layer CPL may extend along the top and outside of the stopper STP to the outer side surface SIDE_INS of the insulating layer stack INS.

Referring to FIG. 4, the common intermediate layer EL_COM, the cathode CAT and the capping layer CPL may be disposed on the outer side surface SIDE_INS of the insulating layer stack INS.

As described above, the stopper STP may be disposed on the outer side surface of the third light emitting element ED3, which is the outermost light emitting element ED among the plurality of light emitting elements ED1, ED2 and ED3 corresponding to a plurality of subpixels SP, and may have a thickness thicker than the third anode AND3 of the third light emitting element ED3 which is the outermost light emitting element ED.

Referring to FIG. 4, the bottom surface of the stopper STP may have a larger area than the top surface of the stopper STP. The stopper STP may include a first stopper on the insulating layer stack INS and a second stopper on the first stopper. The first stopper may include the same material as the bank BK, and the second stopper may include the same material as a spacer on the bank BK. The bank BK and the spacer may include organic materials.

Each of the first inorganic layer PAS1 and the second inorganic layer PAS2 may be formed of silicon nitride, aluminum nitride, zirconium nitride, titanium nitride, hafnium nitride, tantalum nitride, silicon oxide, aluminum oxide, or titanium oxide.

For example, the organic layer PCL may be formed of acryl resin, epoxy resin, phenolic resin, polyamide resin or polyimide resin. The organic layer PCL may be applied in a liquid form through an inkjet process, and then, may be formed through a curing process.

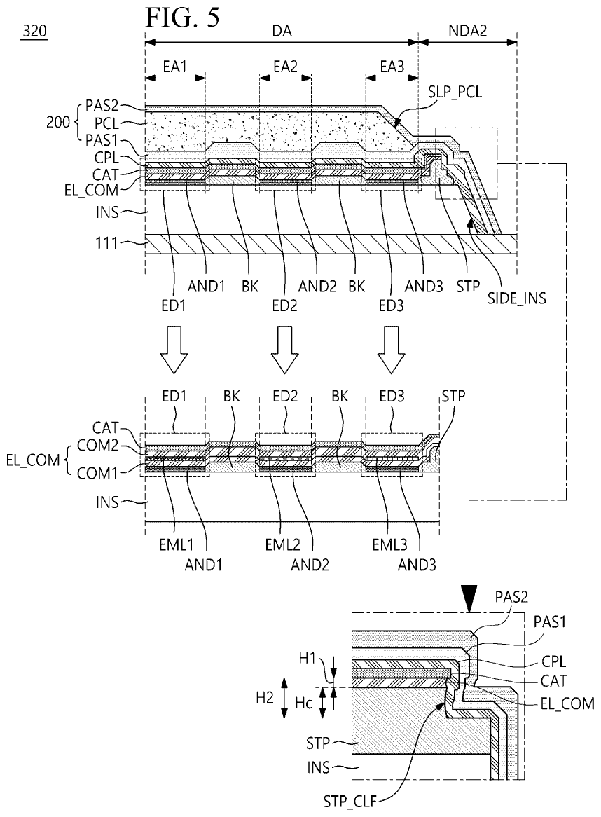

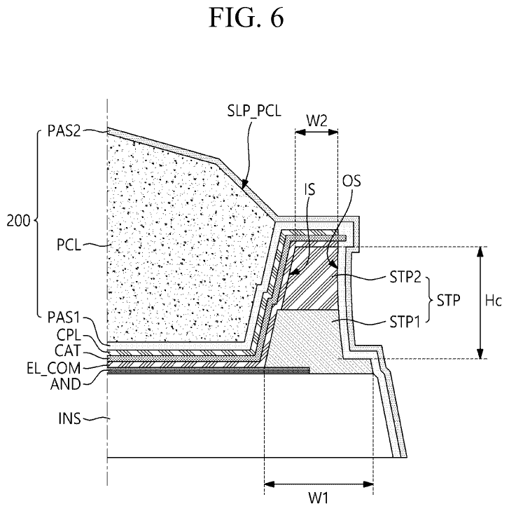

FIG. 5 is a cross-sectional view of a display panel 110 according to aspects of the present disclosure, and FIG. 6 is a cross-sectional view of the outer area of the display panel 110 according to the aspects of the present disclosure. FIG. 6 is an enlarged cross-sectional view showing an area where a stopper STP is located.

Like the cross-sectional view of FIG. 4, the cross-sectional view of FIG. 5 is a cross-sectional view for the area 320 including the second non-display area NDA2 and the display area DA adjacent thereto.

The cross-sectional view of FIG. 5 differs from the cross-sectional view of FIG. 4 only in the shape and structure of the stopper STP and the patterning shapes and locations of the common intermediate layer EL_COM and the cathode CAT, and is the same as the cross-sectional view of FIG. 4 in all of the others. Therefore, hereinbelow, description will be made mainly on differences from the cross-sectional view of FIG. 4.

Referring to FIGS. 5 and 6, the outer side surface of the stopper STP may be an etched surface. Accordingly, the inner side surface and the outer side surface of the stopper STP may have different shapes and slopes.

Referring to FIGS. 5 and 6, an outer side surface OS of the stopper STP may have a slope that is almost vertical, and an inner side surface IS of the stopper STP may have a slope gentler than the outer side surface OS of the stopper STP. That is to say, the outer side surface OS of the stopper STP may have a steeper slope than the inner side surface IS of the stopper STP.

Referring to FIGS. 5 and 6, the stopper STP may include a first stopper STP1 on the insulating layer stack INS and a second stopper STP2 on the first stopper STP1.

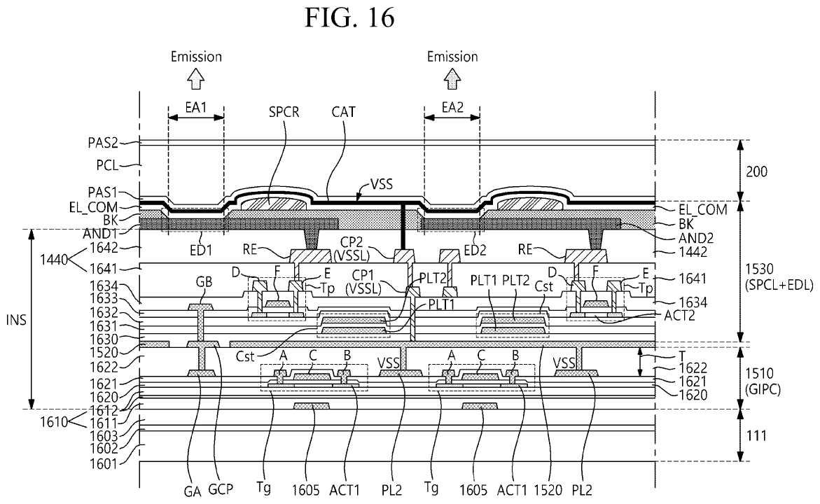

The first stopper STP1 may include the same material as the bank BK, and the second stopper STP2 may include the same material as a spacer (SPCR of FIG. 16) which is located on the bank BK. In other words, the first stopper STP1 may be located in the same material layer as the bank BK, and the second stopper STP2 may be located in the same material layer as the spacer. The bank BK and the spacer may include organic materials.

Referring to FIGS. 5 and 6, the end of the common intermediate layer EL_COM and the end of the cathode CAT may be located on the stopper STP. Namely, the common intermediate layer EL_COM and the cathode CAT may end at the top of the stopper STP, and may not extend to the outer side surface OS of the stopper STP.

Referring to FIGS. 5 and 6, although the common intermediate layer EL_COM and the cathode CAT end at the top of the stopper STP, the capping layer CPL, the first inorganic layer PAS1 and the second inorganic layer PAS2 may not end at the top of the stopper STP and may extend beyond the outer side surface OS of the stopper STP to the outer side surface SIDE_INS of the insulating layer stack INS.

Referring to FIGS. 5 and 6, the second stopper STP2 and the common intermediate layer EL_COM may include organic materials, and the cathode CAT may include an inorganic material. Accordingly, when, in the manufacture of a panel, etching the second stopper STP2, the common intermediate layer EL_COM and the cathode CAT through an etching process (e.g., a dry etching process), characteristics according to which the second stopper STP2 and the common intermediate layer EL_COM are etched may be different from characteristics according to which the cathode CAT is etched. Accordingly, the end of the cathode CAT may protrude further outward than the outer side surface OS of the second stopper STP2 and the end of the common intermediate layer EL_COM.

Referring to FIGS. 5 and 6, the end of the common intermediate layer EL_COM may be located over the insulating layer stack INS. The end of the common intermediate layer EL_COM may overlap the insulating layer stack INS.

Referring to FIG. 5, the stopper STP may include a cliff portion STP_CLF from the top to a point where the slope of the outer side surface OS is gentle below a predetermined level or to a point where there is a step.

Referring to FIG. 5, a value H2 obtained by summing a height Hc of the cliff portion STP_CLF of the stopper STP and a height H1 of the common intermediate layer EL_COM may be larger than the sum of the thickness of the first inorganic layer PAS1 and the thickness of the second inorganic layer PAS2.

For example, the value H2 obtained by summing the height He of the cliff portion STP_CLF of the stopper STP and the height H1 of the common intermediate layer EL_COM may be equal to or larger than 1.3 times the sum of the thickness of the first inorganic layer PAS1 and the thickness of the second inorganic layer PAS2 (H2≥(T1+T2)*1.3).

Referring to FIG. 5, as the outer side surface OS of the stopper STP is etched, the width of the bottom surface of the stopper STP may be larger than the width of the top surface of the stopper STP.

Referring to FIGS. 5 and 6, the slope of the outer side surface of the cliff portion STP_CLF of the stopper STP may be almost vertical. The height Hc of the cliff portion STP_CLF of the stopper STP may be adjusted depending on a dry etching time. The longer the dry etching time is, the higher the height Hc of the cliff portion STP_CLF of the stopper STP may be.

Referring to FIG. 6, the lower end portion of the outer side surface of the first stopper STP1 may protrude further outward than the upper end portion of the outer side surface of the second stopper STP2.

For example, if the dry etching time is set to be shorter than a first time, only a portion of the outer side surface of the second stopper STP2 may be etched, and the outer side surface of the first stopper STP1 may not be etched. In this case, the cliff height Hc of the stopper STP may correspond to a portion of the thickness of the second stopper STP2.

For another example, if the dry etching time is set to be the first time, the entire outer side surface of the second stopper STP2 may be etched, and the outer side surface of the first stopper STP1 may not be etched. In this case, the cliff height Hc of the stopper STP may be the thickness of the second stopper STP2.

For still another example, if the dry etching time is set to be a second time longer than the first time, both the outer side surface of the second stopper STP2 and the outer side surface of the first stopper STP1 may be etched. In this case, the cliff height Hc of the stopper STP may be a value obtained by summing the thickness of the second stopper STP2 and the thickness of the first stopper STP1.

For yet still another example, if the dry etching time is set to be longer than the first time and shorter than the second time, as shown in FIG. 6, the entire outer side surface of the second stopper STP2 may be etched, and only a portion of the outer side surface of the first stopper STP1 may be etched. In this case, as shown in FIG. 6, the cliff height Hc of the stopper STP may be a value obtained by summing the thickness of the second stopper STP2 and an etched depth of the first stopper STP1. In addition, the outer side surface of the first stopper STP1 may protrude further outward than the outer side surface of the second stopper STP2.

For further yet still another example, if the dry etching time is set to be longer than the second time, both the outer side surface of the second stopper STP2 and the outer side surface of the first stopper STP1 may be etched, and a portion of the upper layer portion of the insulating layer stack INS may also be etched. In this case, the cliff height Hc of the stopper STP may be a value obtained by summing the thickness of the second stopper STP2, the thickness of the first stopper STP1 and an etched depth of the insulating layer stack INS.

Referring to FIG. 6, as the outer side surface OS of the stopper STP is etched, a width W1 of the bottom surface of the first stopper STP1 may be larger than a width W2 of the top surface of the second stopper STP2.

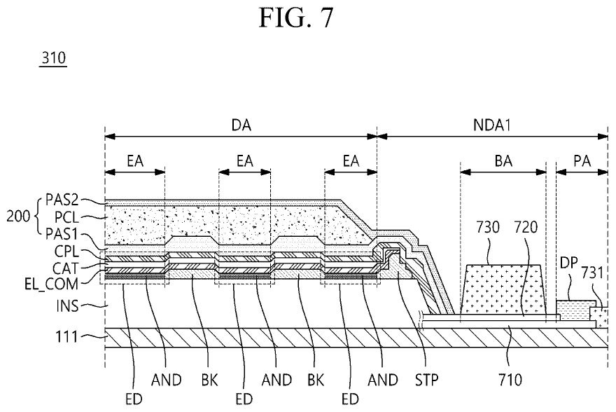

FIG. 7 is a cross-sectional view of a display panel 110 according to aspects of the present disclosure.

FIG. 7 is a cross-sectional view for the area 310 including the first non-display area NDA1 and the display area DA adjacent thereto in FIG. 3. Hereinafter, description for the same features as those of the cross-sectional structure of FIG. 5 will be omitted, and description will be made mainly on differences from the cross-sectional structure of FIG. 6.

Referring to FIG. 7, the first non-display area NDA1 may include a bending area BA and a pad area PA.

The bending area BA may include a bending layer 730 which is disposed on the substrate 111. The bending layer 730 may be a bending organic layer which includes an organic material.

The pad area PA may include a display pad DP to which a circuit for display driving (e.g., a data driving circuit) or a printed circuit board is electrically connected. The display pad DP may be electrically connected to a display signal line (e.g., a data line, a first common driving voltage line or a second common driving voltage line) disposed in the display area DA.

In the display panel 110, a display connecting line 710 which electrically connects the display signal line (e.g., the data line, the first common driving voltage line or the second common driving voltage line) disposed in the display area DA and the display pad DP may be disposed.

The display connecting line 710 may pass through the bending area BA and extend to the pad area PA. To this end, when the display connecting line 710 passes through the bending area BA, the display connecting line 710 may pass under the bending layer 730 of the bending area BA.

The display connecting line 710 may overlap the bending layer 730 of the bending area BA. An insulating layer 720 may be disposed between the display connecting line 710 and the bending layer 730. The insulating layer 720 may be a layer which extends from the display area DA, and may be a layer which is included in the insulating layer stack INS.

The display connecting line 710 may include the same material as the source and drain electrodes of a transistor (e.g., DT or ST) disposed in the display area DA.

Alternatively, the display connecting line 710 may be composed of a first touch connection pattern which includes the same material as the source and drain electrodes of a transistor (e.g., DT or ST) disposed in the display area DA and a second touch connection pattern which includes the same material as the gate electrode of the transistor (e.g., DT or ST) or the gate line GL.

The bending layer 730 may be disposed in the bending area BA, and may be disposed to cover a portion of the display connecting line 710. The bending layer 730 may prevent the display connecting line 710 from being exposed to the outside in the bending area BA where the substrate 111 is bent, and may serve to protect the display connecting line 710. An open hole which exposes the top of the bending layer 730 may be defined. That is to say, by removing inorganic layers (e.g., the first inorganic layer PAS1, the second inorganic layer PAS2, etc.) which may be disposed on the bending layer 730, the open hole may be formed. In the case where an inorganic layer is disposed on the bending layer 730, when the bending area BA is bent, a crack may occur in the inorganic layer, and moisture, etc. may penetrate into the inorganic layer in which the crack has occurred. Therefore, the inorganic layers defined on the bending layer 730 are removed.

A pattern protection layer 731 may be disposed to surround the end of the display connecting line 710 to protect the end of a touch connection pattern 1200 disposed at the edge of the first non-display area NDA1.

The bending layer 730 and the pattern protection layer 731 may be disposed at the same layer as the planarization layer included in the insulating layer stack INS, and may be made of the same material as the planarization layer.

For example, the bending layer 730 and the pattern protection layer 731 may be formed as an organic layer made of acryl resin, epoxy resin, phenolic resin, polyamide resin or polyimide resin.

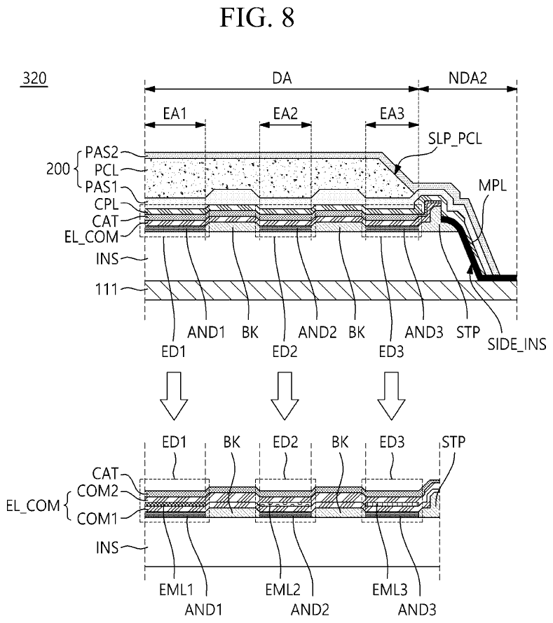

FIG. 8 is a cross-sectional view of another display panel 110 according to aspects of the present disclosure.

Referring to FIG. 8, the display panel 110 according to the aspects of the present disclosure may further include a patterning organic material MPL which is disposed outside the stopper STP.

On the outer side surface SIDE_INS of the insulating layer stack INS, the patterning organic material MPL may be disposed between the outer side surface SIDE_INS of the insulating layer stack INS and the capping layer CPL.

The patterning organic material MPL may also be disposed on the substrate 111.

As shown in FIGS. 5 to 7, the cathode CAT exists from the display area DA to only the top of the stopper STP, and does not exist from the outer side surface of the stopper STP.

The reason the cathode CAT is disposed in this way is because the cathode CAT is related with the method of a cathode patterning process.

The cathode patterning process may proceed as follows.

The patterning organic material MPL is deposited in an area where the cathode CAT is not disposed (i.e., the outer area of the stopper STP), and a cathode material is deposited thereon. For example, the patterning organic material MPL may include an organic material. The cathode material may include a magnesium-silver (Mg—Ag) alloy.

The cathode material may be deposited only in an area where the patterning organic material MPL does not exist. Accordingly, the cathode CAT may be formed only in a desired area (the area where the patterning organic material MPL does not exist).

The patterning organic material MPL may have low adhesion characteristics with a metal due to low surface energy of the material thereof or high interfacial energy with the cathode material (the metal). Accordingly, when depositing the cathode material (the metal), the probability of desorption of the cathode material (the metal) from the surface of the patterning organic material MPL may be significantly high. Due to this fact, nucleation of the cathode material (the metal) does not occur. Therefore, the cathode material may be deposited only in an area where the patterning organic material MPL does not exist.

Meanwhile, as shown in FIGS. 5 and 7, the display panel 110 for which the manufacturing process is completed may be in a state in which the patterning organic material MPL is completely removed.

Unlike this, as shown in FIG. 8, the display panel 110 for which the manufacturing process is completed may be in a state in which the entirety or a part of the patterning organic material MPL remains.

As described above, as shown in FIGS. 5 to 8, in the display panel 110 according to the aspects of the present disclosure, the stopper STP, which is an organic layer overflow prevention structure, is not disposed on the side surface of the insulating layer stack INS but is disposed on the insulating layer stack INS. Accordingly, it is possible to prevent the bezel from increasing due to the presence of the stopper STP, which is an organic layer overflow prevention structure. In other words, in the display panel 110 according to the aspects of the present disclosure, the stopper STP may be not only an organic layer overflow prevention structure but also one of extremely narrow bezel structures.

In the case of the display panel 110 of FIG. 4, the outer side surface of the stopper STP is not etched, and the common intermediate layer EL_COM and the cathode CAT are disposed to extend to the outside of the stopper STP. If the common intermediate layer EL_COM, which is an organic layer included in the light emitting element intermediate layer EL, is disposed to extend to the outside of the stopper STP, the characteristics of the common intermediate layer EL_COM may change in an area outside the stopper STP due to external factors. Thus, if the common intermediate layer EL_COM is disposed to extend to the outside of the stopper STP, there is a possibility that the reliability of the light emitting elements ED is likely to deteriorate.

As shown in FIG. 4, as the outer side surface of the stopper STP is not etched and the common intermediate layer EL_COM and cathode CAT are disposed to extend to the outside of the stopper STP, the bezel may slightly increase.

In comparison with this, in the case of the display panel 110 of FIGS. 5 to 8, the outer side surface of the stopper STP is etched, and the common intermediate layer EL_COM and cathode CAT are not disposed to extend to the outside of the stopper STP.

Hence, in the case of the display panel 110 of FIGS. 5 to 8, when compared to the display panel 110 of FIG. 4, reliability of the light emitting elements ED may relatively increase, and a smaller bezel may be formed.

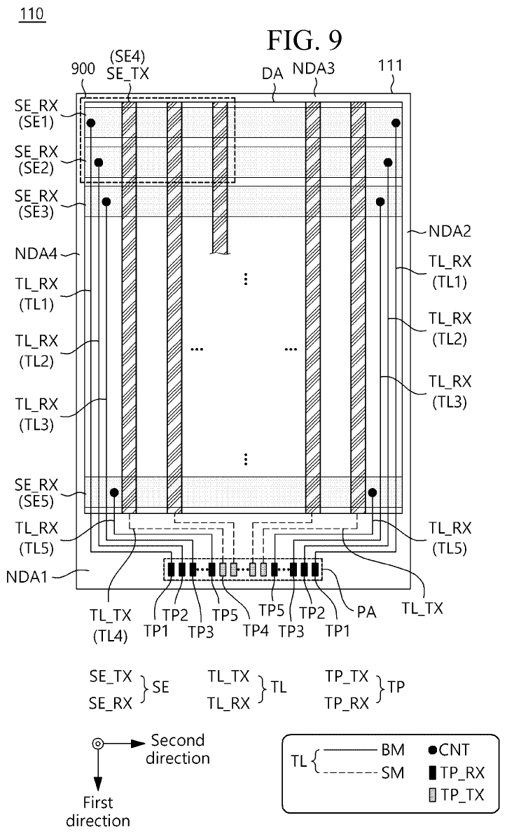

In the above, the stopper STP as an extremely narrow bezel structure has been described. Hereinafter, an internal touch routing structure, which is another extremely narrow bezel structure, will be described with reference to FIGS. 9 to 13.

FIG. 9 is a plan view showing a touch sensor included in a display panel 110 according to aspects of the present disclosure.

Referring to FIG. 9, a substrate 111 of the display panel 110 according to the aspects of the present disclosure may include a display area DA where a plurality of subpixels SP are disposed, and a non-display area NDA as an outer area of the display area DA.

Referring to FIG. 9, the non-display area NDA may include a first non-display area NDA which is located in a first direction from the display area DA, a second non-display area NDA2 which is located in a second direction from the display area DA, a third non-display area NDA3 which is located in a direction opposite to the first direction from the display area DA, and a fourth non-display area NDA4 which is located in a direction opposite to the second direction from the display area DA. The first non-display area NDA1 may include a pad area PA where a plurality of touch pads TP are disposed.

Referring to FIG. 9, the display panel 110 according to the aspects of the present disclosure may include the touch sensor layer TSL which is disposed on the second inorganic layer PAS2 and includes a plurality of sensor electrodes SE disposed in the display area DA. The display panel 110 according to the aspects of the present disclosure may further include a plurality of touch routing lines TL for electrically connecting the plurality of sensor electrodes SE and the plurality of touch pads TP. The plurality of touch routing lines TL may be regarded as components included in a touch sensor.

Referring to FIG. 9, the plurality of sensor electrodes SE may include a first sensor electrode SE1, a second sensor electrode SE2, a third sensor electrode SE3, a fourth sensor electrode SE4 and a fifth sensor electrode SE5.

Each of the first sensor electrode SE1, the second sensor electrode SE2, the third sensor electrode SE3 and the fifth sensor electrode SE5 may extend in the second direction. The second direction may correspond to a direction in which the gate line GL extends.

The fourth sensor electrode SE4 may extend in the first direction. The first direction may correspond to a direction in which the data line DL extends.

Referring to FIG. 9, the plurality of touch routing lines TL may include a first touch routing line TL1 for electrically connecting the first sensor electrode SE1 to a first touch pad TP1 disposed in the pad area PA, a second touch routing line TL2 for electrically connecting the second sensor electrode SE2 to a second touch pad TP2 disposed in the pad area PA, a third touch routing line TL3 for electrically connecting the third sensor electrode SE3 to a third touch pad TP3 disposed in the pad area PA, a fourth touch routing line TLA for electrically connecting the fourth sensor electrode SE4 to a fourth touch pad TP4 disposed in the pad area PA, and a fifth touch routing line TL5 for electrically connecting the fifth sensor electrode SE5 to a fifth touch pad TP5 disposed in the pad area PA.

Referring to FIG. 9, the first touch routing line TL1, the second touch routing line TL2, the third touch routing line TL3 and the fifth touch routing line TL5 may be connected to the sensor electrodes SE1, SE2, SE3 and SE5, respectively, extending in the second direction (the row direction).

Referring to FIG. 9, each of the first touch routing line TL1, the second touch routing line TL2, the third touch routing line TL3 and the fifth touch routing line TL5 may extend to the first non-display area NDA1 by traversing the display area DA in the first direction, without bypassing the second non-display area NDA2 and the fourth non-display area NDA4. In embodiments of the present disclosure, the fact that the touch routing line does not bypass the second non-display area NDA2 and the fourth non-display area NDA4 means that the touch routing line does not pass through the second non-display area NDA2 and the fourth non-display area NDA4.

Referring to FIG. 9, the plurality of sensor electrodes SE may include a plurality of transmission sensor electrodes SE_TX and a plurality of reception sensor electrodes SE_RX. The plurality of touch routing lines TL may include a plurality of transmission touch routing lines TL_TX and a plurality of reception touch routing lines TL_RX. The plurality of touch pads TP may include a plurality of transmission touch pads TP_TX and a plurality of reception touch pads TP_RX.

A touch driving signal outputted from the touch sensing circuit 210 may be applied to at least one of the plurality of transmission sensor electrodes SE_TX. The touch driving signal may be a signal whose voltage level changes. For example, the touch driving signal may be a pulse signal with a predetermined frequency and amplitude, or may be a signal with various signal waveforms such as a triangle wave, a square wave or a sine wave.

Referring to FIG. 9, the plurality of transmission sensor electrodes SE_TX and the plurality of reception sensor electrodes SE_RX may be disposed to intersect each other. For example, each of the plurality of transmission sensor electrodes SE_TX may be disposed to extend in the first direction. Each of the plurality of reception sensor electrodes SE_RX may be disposed to extend in the second direction different from the first direction.

The shape of each of the plurality of transmission sensor electrodes SE_TX and the plurality of reception sensor electrodes SE_RX may be changed in various ways. For example, each of the plurality of transmission sensor electrodes SE_TX and the plurality of reception sensor electrodes SE_RX may be a bar shape. For another example, each of the plurality of reception sensor electrodes SE_RX may be composed of several electrically connected sub sensor electrodes, or each of the plurality of transmission sensor electrodes SE_TX may be composed of several electrically connected sub sensor electrodes. For example, each of the several sub sensor electrodes may have various shapes such as a square, a diamond or a comb-tooth pattern.

Referring R to FIG. 9, the display panel 110 according to the aspects of the present disclosure may include an internal touch routing structure as an extremely narrow bezel structure.

The internal touch routing structure may be a structure in which the touch routing line TL is not disposed in the second to fourth non-display areas NDA2 to NDA4 excluding the first non-display area NDA1 where the pad area PA is included, among the first to fourth non-display areas NDA1 to NDA4.

According to the internal touch routing structure, among the plurality of transmission touch routing lines TL_TX and the plurality of reception touch routing lines TL_RX, a plurality of touch routing lines (e.g., the plurality of reception touch routing lines TL_RX) which extend in the column direction (the first direction) may extend to the pad area PA in the first non-display area NDA1 by traversing the display area DA, without bypassing the second to fourth non-display areas NDA2 to NDA4 outside the display area DA.

For example, among the plurality of transmission touch routing lines TL_TX and the plurality of reception touch routing lines TL_RX, each of the plurality of reception touch routing lines TL_RX each of which extends in the first direction may extend to the pad area PA in the first non-display area NDA1 by traversing the display area DA, without bypassing the second to fourth non-display areas NDA2 to NDA4 outside the display area DA.

When the plurality of reception touch routing lines TL_RX traverse the display area DA, the plurality of reception touch routing lines TL_RX may be disposed to bypass the light emitting area of each of the plurality of subpixels SP in the display area DA. Accordingly, it is possible to design the internal touch routing structure without deterioration in light emission performance.

In this case, the plurality of reception touch routing lines TL_RX may intersect the plurality of reception sensor electrodes SE_RX. In other words, the plurality of reception touch routing lines TL_RX may be located in a metal layer different from that of the plurality of reception sensor electrodes SE_RX, and may overlap the plurality of reception sensor electrodes SE_RX.

According to the internal touch routing structure of the display panel 110 according to the aspects of the present disclosure, the size of the non-display area NDA may be significantly reduced. Namely, the sizes of the second to fourth non-display areas NDA2, NDA3 and NDA4 which do not include the pad area PA may be significantly reduced.

Referring to FIG. 9, when the internal touch routing structure of the display panel 110 according to the aspects of the present disclosure is applied, among the first to fourth non-display areas NDA1 to NDA4, the plurality of touch routing lines TL may be disposed in the first non-display area NDA1 including the pad area PA, but the plurality of touch routing lines TL may not be disposed in the second non-display area NDA2 to the fourth non-display area NDA4. Accordingly, the sizes of the second to fourth non-display areas NDA2, NDA3 and NDA4 among the first to fourth non-display areas NDA1 to NDA4 may be reduced to a limit.

Referring to FIG. 9, the plurality of transmission sensor electrodes SE_TX and the plurality of reception sensor electrodes SE_RX may include a sensor metal.

A plurality of transmission touch routing lines TL_TX or a plurality of reception touch routing lines TL_RX may intersect a plurality of transmission sensor electrodes SE_TX or a plurality of reception sensor electrodes SE_RX. Accordingly, the plurality of transmission touch routing lines TL_TX or the plurality of reception touch routing lines TL_RX may include a bridge metal different from the sensor metal included in the plurality of transmission sensor electrodes SE_TX or the plurality of reception sensor electrodes SE_RX.

For example, as shown in FIG. 9, among the plurality of transmission touch routing lines TL_TX and the plurality of reception touch routing lines TL_RX, the plurality of reception touch routing lines TL_RX may intersect the plurality of reception sensor electrodes SE_RX while traversing the display area DA.

In this case, the plurality of reception touch routing lines TL_RX may include the bridge metal different from the sensor metal. At this time, the plurality of transmission touch routing lines TL_TX may include the sensor metal or the bridge metal.

For another example, among the plurality of transmission touch routing lines TL_TX and the plurality of reception touch routing lines TL_RX, the plurality of transmission touch routing lines TL_TX may intersect the plurality of transmission sensor electrodes SE_TX while traversing the display area DA. In this case, the plurality of transmission touch routing lines TL_TX may include the bridge metal different from the sensor metal. At this time, the plurality of reception touch routing lines TL_RX may include the sensor metal or the bridge metal.

Meanwhile, outside the display area DA (i.e., the first non-display area NDA1), the touch routing lines TL may be changed from the sensor metal to the bridge metal or from the bridge metal to the sensor metal. As the occasion demands, a third metal different from the sensor metal and the bridge metal may be used as a metal of some of the touch routing lines TL.

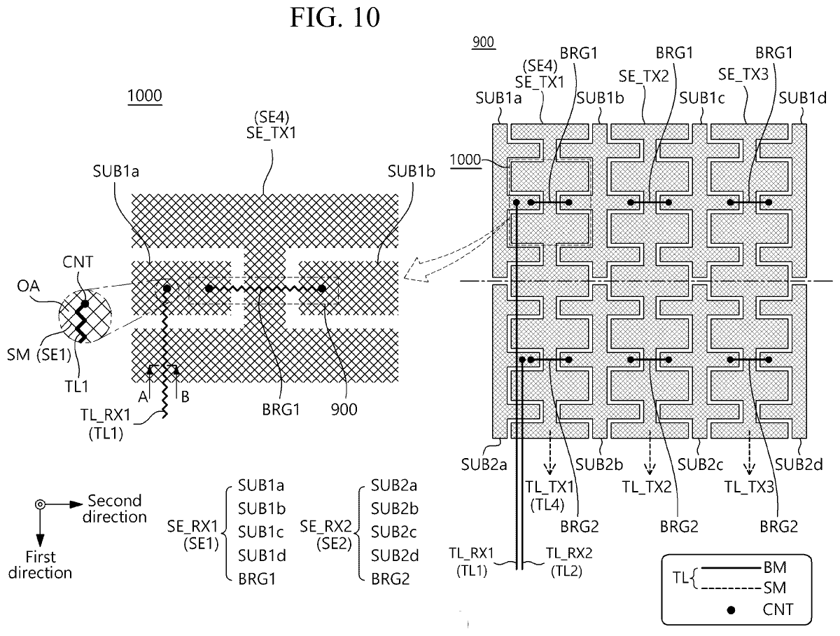

FIG. 10 shows in detail as an example a partial area 900 of a touch sensor included in a display panel 110 according to aspects of the present disclosure. FIG. 10 shows an enlarged view of a unit sensor 1000 in the partial area 900 of the touch sensor. The unit sensor 1000 may mean an area where one transmission touch sensor electrode SE_TX and one reception touch sensor electrode SE_RX intersect.

FIG. 10 is an enlarged plan view of the partial area 900 of FIG. 9, and shows as an example that each sensor electrode SE included in the touch sensor has a comb-tooth shape.

Referring to FIG. 10, one sensor electrode SE may be composed of one integrated electrode or may be composed of several sub sensor electrodes which are electrically connected.

Referring to FIG. 10, in the partial area 900 of the touch sensor of FIG. 9, a first reception sensor electrode SE_RX1 and a second reception sensor electrode SE_RX2 each of which extends in the second direction (e.g., the row direction) may be disposed, and a first transmission sensor electrode SE_TX1, a second transmission sensor electrode SE_TX2 and a third transmission sensor electrode SE_TX3 each of which extends in the first direction (e.g., the column direction) may be disposed. The first direction and the second direction may be directions that intersect each other.

Referring to FIG. 10, in the partial area 900 of the touch sensor of FIG. 9, a first reception touch routing line TL_RX1 which is electrically connected to the first reception sensor electrode SE_RX1 and a second reception touch routing line TL_RX2 which is electrically connected to the second reception sensor electrode SE_RX2 may be further disposed.

Referring to FIG. 10, the first transmission sensor electrode SE_TX1, the second transmission sensor electrode SE_TX2 and the third transmission sensor electrode SE_TX3 may be electrically connected to a first transmission touch routing line TL_TX1, a second transmission touch routing line TL_TX2 and a third transmission touch routing line TL_TX3, respectively, in the first non-display area NDA1 or adjacent thereto.

Hereinafter, the first reception sensor electrode SE_RX1 is also referred to as the first sensor electrode SE1, the second reception sensor electrode SE_RX2 is also referred to as the second sensor electrode SE2, and the first transmission sensor electrode SE_TX1 is also referred to as the fourth sensor electrode SE4. In addition, the first reception touch routing line TL_RX1 is also referred to as the first touch routing line TL1, the second reception touch routing line TL_RX2 is also referred to as the second touch routing line TL2, and the first transmission touch routing line TL_TX1 is also referred to as the fourth touch routing line TL4. The first reception touch pad TP_RX to which the first reception sensor electrode SE_RX1 is connected through the first reception touch routing line TL_RX1 is also referred to as the first touch pad TP1, the second reception touch pad TP_RX to which the second reception sensor electrode SE_RX2 is connected through the second reception touch routing line TL_RX2 is also referred to as the second touch pad TP2, and the first transmission touch pad TP_TX to which the first transmission sensor electrode SE_TX1 is connected through the first transmission touch routing line TL_RX2 is also referred to as the fourth touch pad TP4.

Likewise, a third reception sensor electrode SE_RX which is disposed adjacent to the second reception sensor electrode SE2 in the first direction is also referred to as the third sensor electrode SE3, and a reception sensor electrode SE_RX which is disposed closest to the pad area PA among the plurality of reception sensor electrodes SE_RX is also referred to as the fifth sensor electrode SE5. A reception touch routing line TL_RX which is connected to the third sensor electrode SE3 is also referred to as a third touch routing line TL3, and a reception touch routing line TL_RX which is connected to the fifth sensor electrode SE5 is also referred to as a fifth touch routing line TL_RX. A reception touch pad TP_RX to which the third sensor electrode SE3 is connected through the third touch routing line TL3 is also referred to as the third touch pad TP3, and a reception touch pad TP_RX to which the fifth sensor electrode SE5 is connected through the fifth touch routing line TL5 is also referred to as the fifth touch pad TP5.

Each of the first, second and third transmission sensor electrodes SE_TX1, SE_TX2 and SE_TX3 may be composed of one integrated electrode. The first reception sensor electrode SE_RX1 may be composed of a plurality of first sub sensor electrodes SUBla, SUB1b, SUBIc and SUB1d which are electrically connected by first bridges BRG1. The second reception sensor electrode SE_RX2 may be composed of a plurality of second sub sensor electrodes SUB2a, SUB2b, SUB2c and SUB2d which are electrically connected by second bridges BRG2.

The first bridges BRG1 may overlap the first, second and third transmission sensor electrodes SE_TX1, SE_TX2 and SE_TX3. The second bridges BRG2 may overlap the first, second and third transmission sensor electrodes SE_TX1, SE_TX2 and SE_TX3.

Referring to FIG. 10, the first transmission sensor electrode SE_TX1 may pass between the two first sub sensor electrodes SUBla and SUBlb included in the first reception sensor electrode SE_RX1 and between the two second sub sensor electrodes SUB2a and SUB2b included in the second reception sensor electrode SE_RX2.

The first bridge BRG1 which electrically connects the two first sub sensor electrodes SUBla and SUB1b included in the first reception sensor electrode SE_RX1 may overlap the first transmission sensor electrode SE_TX1.

The second bridge BRG2 which electrically connects the two second sub sensor electrodes SUB2a and SUB2b included in the second reception sensor electrode SE_RX2 may overlap the first transmission sensor electrode SE_TX1.

Referring to FIG. 10, the second transmission sensor electrode SE_TX2 may pass between the two first sub sensor electrodes SUB1b and SUBIc included in the first reception sensor electrode SE_RX1 and between the two second sub sensor electrodes SUB2b and SUB2c included in the second reception sensor electrode SE_RX2.

The first bridge BRG1 which electrically connects the two first sub sensor electrodes SUB1b and SUB Ic included in the first reception sensor electrode SE_RX1 may overlap the second transmission sensor electrode SE_TX2.

The second bridge BRG2 which electrically connects the two second sub sensor electrodes SUB2b and SUB2c included in the second reception sensor electrode SE_RX2 may overlap the second transmission sensor electrode SE_TX2.

Referring to FIG. 10, the third transmission sensor electrode SE_TX3 may pass between the two first sub sensor electrodes SUBIc and SUBld included in the first reception sensor electrode SE_RX1 and between the two second sub sensor electrodes SUB2c and SUB2d included in the second reception sensor electrode SE_RX2.

The first bridge BRG1 which electrically connects the two first sub sensor electrodes SUB1c and SUB1d included in the first reception sensor electrode SE_RX1 may overlap the third transmission sensor electrode SE_TX3.

The second bridge BRG2 which electrically connects the two second sub sensor electrodes SUB2c and SUB2d included in the second reception sensor electrode SE_RX2 may overlap the third transmission sensor electrode SE_TX3.

Referring to FIG. 10, the first reception touch routing line TL_RX1 may be electrically connected to at least one (e.g., SUBla) of the plurality of first sub sensor electrodes SUBla, SUB1b, SUB1c and SUB1d constituting the first reception sensor electrode SE_RX1, through a contact hole CNT.

The second reception touch routing line TL_RX2 may be electrically connected to at least one (e.g., SUB2a) of the plurality of second sub sensor electrodes SUB2a, SUB2b, SUB2c and SUB2d constituting the second reception sensor electrode SE_RX2, through a contact hole CNT.

Referring to FIG. 10, the first transmission sensor electrode SE_TX1 may be electrically connected to the first transmission touch routing line TL_TX1 at a point closest to the first non-display area NDA1. Unlike this, the first transmission sensor electrode SE_TX1 may extend to the first non-display area NDA1. A portion of the first transmission sensor electrode SE_TX1 which extends to the first non-display area NDA1 may correspond to the first transmission touch routing line TL_TX1.

The second transmission sensor electrode SE_TX2 may be electrically connected to the second transmission touch routing line TL_TX2 at a point closest to the first non-display area NDA1. Unlike this, the second transmission sensor electrode SE_TX2 may extend to the first non-display area NDA1. A portion of the second transmission sensor electrode SE_TX2 which extends to the first non-display area NDA1 may correspond to the second transmission touch routing line TL_TX2.

The third transmission sensor electrode SE_TX3 may be electrically connected to the third transmission touch routing line TL_TX3 at a point closest to the first non-display area NDA1. Unlike this, the third transmission sensor electrode SE_TX3 may extend to the first non-display area NDA1. A portion of the third transmission sensor electrode SE_TX3 which extends to the first non-display area NDA1 may correspond to the third transmission touch routing line TL_TX3.

Referring to FIG. 10, the plurality of first sub sensor electrodes SUB1a, SUB1b, SUB1c and SUB1d which are included in the first reception sensor electrode SE_RX1 and the plurality of second sub sensor electrodes SUB2a, SUB2b, SUB2c and SUB2d included in the second reception sensor electrode SE_RX2 may be composed of a sensor metal disposed in a sensor metal layer.

The first bridges BRG1 and the second bridge BRG2 may be composed of a bridge metal disposed in a bridge metal layer which is a metal layer different from the sensor metal layer.

An insulating layer may exist between the bridge metal layer and the sensor metal layer.

Referring to FIG. 10, the first reception touch routing line TL_RX1 may overlap the first transmission sensor electrode SE_TX1 and/or the second reception sensor electrode SE_RX2 which are disposed in a sensor metal layer and should be electrically separated. Accordingly, the first reception touch routing line TL_RX1 should be disposed in a bridge metal layer different from a sensor metal layer. That is to say, the first reception touch routing line TL_RX1 may include a bridge metal.

The second reception touch routing line TL_RX2 may overlap the first transmission sensor electrode SE_TX1 and/or the first reception sensor electrode SE_RX1 which are disposed in a sensor metal layer and should be electrically separated. Accordingly, the second reception touch routing line TL_RX2 should be disposed in a bridge metal layer different from a sensor metal layer. In other words, the second reception touch routing line TL_RX2 may include a bridge metal.

Referring to FIG. 10, the first transmission touch routing line TL_TX1, the second transmission touch routing line TL_TX2 and the third transmission touch routing line TL_TX3 may be disposed in a sensor metal layer or a bridge metal layer. Namely, the first transmission touch routing line TL_TX1, the second transmission touch routing line TL_TX2 and the third transmission touch routing line TL_TX3 may include a sensor metal or a bridge metal.

For example, in the first non-display area NDA1, in the case where at least one of the first transmission touch routing line TL_TX1, the second transmission touch routing line TL_TX2 and the third transmission touch routing line TL_TX3 intersects or overlaps at least one of the first reception touch routing line TL_TX1 and the second reception touch routing line TL_RX2, the first transmission touch routing line TL_TX1, the second transmission touch routing line TL_TX2 and the third transmission touch routing line TL_TX3 should be disposed in a metal layer different from the first reception touch routing line TL_RX1 and the second reception touch routing line TL_RX2.

Accordingly, in the first non-display area NDA1, in the case where at least one of the first transmission touch routing line TL_TX1, the second transmission touch routing line TL_TX2 and the third transmission touch routing line TL_TX3 intersects or overlaps at least one of the first reception touch routing line TL_TX1 and the second reception touch routing line TL_RX2, the first transmission touch routing line TL_TX1, the second transmission touch routing line TL_TX2 and the third transmission touch routing line TL_TX3 may be disposed in a sensor metal layer. That is to say, the first transmission touch routing line TL_TX1, the second transmission touch routing line TL_TX2 and the third transmission touch routing line TL_TX3 may be composed of a sensor metal.

Referring to FIG. 10, the first sensor electrode SE1 may include the first bridges BRG1 which electrically connect the at least two first sub sensor electrodes SUB1a, SUB1b, SUB1c and SUB1d and the at least two first sub sensor electrodes SUB1a, SUB1b, SUB1c and SUB1d arranged in the second direction. For example, the first sensor electrode SE1 may be the first reception sensor electrode SE_RX1.

Referring to FIG. 10, the first touch routing line TL1 may electrically connect the first sensor electrode SE1 and the first touch pad TP1. One point of the first touch routing line TL1 may be electrically connected to at least one of the at least two first sub sensor electrodes SUB1a, SUB1b, SUB1c and SUB1d included in the first sensor electrode SE1, and another one point of the first touch routing line TL1 may be electrically connected to the first touch pad TP1.

Referring to FIG. 10, the second sensor electrode SE2 may include the second bridges BRG2 which electrically connect the at least two second sub sensor electrodes SUB2a, SUB2b, SUB2c and SUB2d and the at least two second sub sensor electrodes SUB2a, SUB2b, SUB2c and SUB2d arranged in the second direction. For example, the second sensor electrode SE2 may be the second reception sensor electrode SE_RX2.

Referring to FIG. 10, the second touch routing line TL2 may electrically connect the second sensor electrode SE2 and the second touch pad TP2. One point of the second touch routing line TL2 may be electrically connected to at least one of the at least two second sub sensor electrodes SUB2a, SUB2b, SUB2c and SUB2d included in the second sensor electrode SE2, and another point of the second touch routing line TL2 may be electrically connected to the second touch pad TP2.

Referring to FIG. 10, the fourth sensor electrode SE4 may be disposed to pass between the two first sub sensor electrodes SUB1a and SUB1b included in the first sensor electrode SE1 and between the two second sub sensor electrodes SUB2a and SUB2b included in the second sensor electrode SE2.

Referring to FIG. 10, the fourth sensor electrode SE4 may overlap the first bridges BRG1 and the second bridges BRG2.

The fourth touch routing line TL4 may electrically connect the fourth touch pad TP4 which is disposed in the pad area PA included in the first non-display area NDA1 and the fourth sensor electrode SE4 which is disposed in the display area DA.

Referring to FIG. 10, the sensor electrodes SE1 and SE4 of the touch sensor included in the display panel 110 according to the aspects of the present disclosure may be mesh-shaped sensor metals which are formed with openings OA. The openings OA formed in the sensor electrodes SE1 and SE4 may overlap the light emitting areas of the subpixels SP.

In this case, the first touch routing line TL1 connected to the first sensor electrode SE1 and/or the first bridges BRG1 included in the first sensor electrode SE1 may be disposed along mesh-shaped sensor metals which constitute the first sensor electrodes SE1. In other words, the first bridges BRG1 may be disposed while being bent along the mesh-shaped sensor metal of the fourth sensor electrode SE4.

Accordingly, the first touch routing line TL1 connected to the first sensor electrode SE1 and/or the first bridges BRG1 included in the first sensor electrode SE1 may overlap the mesh-shaped sensor metal which constitute the first sensor electrode SE1.

Due to this fact, as the openings OA formed in the first sensor electrode SE1 and the fourth sensor electrode SE4 are not covered by the first touch routing line TL1 and/or the first bridges BRG1, the light emitting areas of the subpixels SP may be widened and light emitting efficiency may be improved.

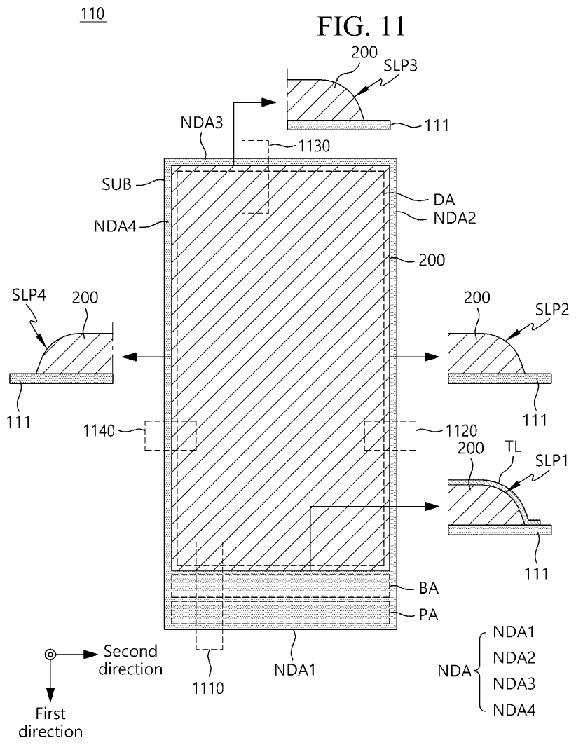

FIG. 11 shows a substrate 110 and an encapsulation layer 200 of a display panel 110 according to aspects of the present disclosure.

Referring to FIG. 11, the non-display area NDA may include a first non-display area NDA1 which is located in a first direction from the display area DA, a second non-display area NDA2 which is located in a second direction from the display area DA, a third non-display area NDA3 which is located in a direction opposite to the first direction from the display area DA, and a fourth non-display area NDA4 which is located in a direction opposite to the second direction from the display area DA.

Referring to FIG. 11, the encapsulation layer 200 may be disposed in the display area DA, and may extend to a partial area of the non-display area NDA.

Referring to FIG. 11, the encapsulation layer 200 may include a first sloped surface SLP1 which is located outside in the first direction with respect to the center of the encapsulation layer 200, a second sloped surface SLP2 which is located outside in the second direction intersecting the first direction with respect to the center of the encapsulation layer 200, a third sloped surface SLP3 which is located outside in the direction opposite to the first direction with respect to the center of the encapsulation layer 200, and a fourth sloped surface SLP4 which is located outside in the direction opposite to the second direction with respect to the center of the encapsulation layer 200. In this case, the edge of the encapsulation layer 200 may be regarded as the edge of the organic layer PCL, and the first to fourth sloped surfaces SLP1, SLP2, SLP3 and SLP4 of the encapsulation layer 200 may be the sloped surfaces of the organic layer PCL. The slope of the first to fourth sloped surfaces SLP1, SLP2, SLP3 and SLP4 of the encapsulation layer 200 may be the slope of the organic layer PCL.

Referring to FIG. 11, the first sloped surface SLP1, the second sloped surface SLP2, the third sloped surface SLP3 and the fourth sloped surface SLP4 of the encapsulation layer 200 may be located in the non-display area NDA.

Referring to FIG. 11, among the first sloped surface SLP1, the second sloped surface SLP2, the third sloped surface SLP3 and the fourth sloped surface SLP4 of the encapsulation layer 200, a metal (e.g., a touch routing line) is not disposed on the second sloped surface SLP2 and the fourth sloped surface SLP2, and the touch routing line TL which is disposed to extend in the first direction may pass on the first sloped surface SLP1.

For example, the first touch routing line TL1 may not be disposed on the second sloped surface SLP2 and the fourth sloped surface SLP4, but may descend along the first sloped surface SLP1 to be electrically connected to the second touch pad TP2 in the pad area PA.

The first touch routing line TL1 may extend to the first non-display area NDA1 including the pad area PA by traversing the display area DA in the first direction, without bypassing the second non-display area NDA2 and the fourth non-display area NDA4. A portion of the first touch routing line TL1 extending to the first non-display area NDA1 may overlap the stopper STP in the first non-display area NDA1.

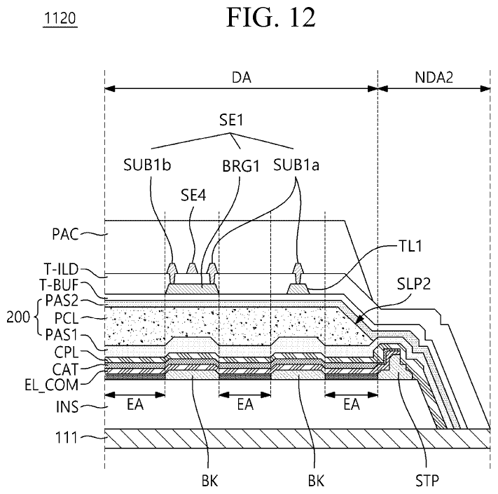

FIG. 12 is a cross-sectional view of a display panel 110 according to aspects of the present disclosure, and is a cross-sectional view of an area 1120 including the second non-display area NDA2 in FIG. 11. In FIG. 11, the vertical structure of each of an area 1130 including the third non-display area NDA3 and an area 1140 including the fourth non-display area NDA4 may be the same as the vertical structure of the area 1120 including the second non-display area NDA2.

Referring to FIG. 12, the vertical structure of an area including the second non-display area NDA2 and a portion of the display area DA adjacent thereto will be described. To this end, the vertical cross-sectional structure of an area where the first sensor electrode SE1 and the first touch routing line TL1 are connected will be described as an example. In the following description, description of a structure which is the same as the vertical cross-sectional structure of FIG. 5 will be omitted, and description will be made mainly on differences from the vertical cross-sectional structure of FIG. 5.

Referring to FIG. 12, the second non-display area NDA2, as an area (e.g., a right area) which is located in the second direction from the display area DA, does not include the bending area BA and the pad area PA.

Referring to FIG. 12, the touch sensor layer TSL may be formed on the encapsulation layer 200.

Referring to FIG. 12, the touch sensor layer TSL may include a touch buffer layer T-BUF on the encapsulation layer 200, a touch interlayer insulating layer T-ILD on the touch buffer layer T-BUF, and a touch protection layer PAC on the touch interlayer insulating layer T-ILD.

Referring to FIG. 12, the touch sensor layer TSL may include a bridge metal layer between the touch buffer layer T-BUF and the touch interlayer insulating layer T-ILD, and a sensor metal layer between the touch interlayer insulating layer T-ILD and the touch protection layer PAC.

Referring to FIG. 12, the touch buffer layer T-BUF may be omitted. The touch buffer layer T-BUF may be an inorganic buffer layer or an organic buffer layer.

Referring to FIG. 12, the touch interlayer insulating layer T-ILD, as an insulating layer for electrical separation between the bridge metal layer and the sensor metal layer, may be an organic buffer layer or an inorganic buffer layer.

Referring to FIG. 12, the touch protection layer PAC may protect a touch sensor by blocking harmful environments from the outside, and may maintain the stability of the characteristics of the display device 100. For example, the touch protection layer PAC may be an organic layer. The touch protection layer PAC may be disposed to extend to the non-display area NDA.

Referring to FIG. 12, the first sensor electrode SE1 which is disposed in the display area DA and extends in the second direction (e.g., the row direction) may be disposed on the encapsulation layer 200.

Referring to FIG. 12, the first sensor electrode SE1 may include the plurality of first sub sensor electrodes SUB1a and SUB1b and the first bridge BRG1 which electrically connects the plurality of first sub sensor electrodes SUB1a and SUB1b.

The first bridge BRG1 of the first sensor electrode SE1 which extends in the second direction (e.g., the row direction) may overlap the fourth sensor electrode SE4 which extends in the first direction (e.g., the column direction).

The plurality of first sub sensor electrodes SUB1a and SUB1b which are included in the first sensor electrode SE1 and the fourth sensor electrode SE4 may be disposed in a sensor metal layer SML. In other words, the plurality of first sub sensor electrodes SUB1a and SUB1b which are included in the first sensor electrode SE1 and the fourth sensor electrode SE4 may include a sensor metal.

The first bridge BRG1 may be disposed in a bridge metal layer BML. In other words, the first bridge BRG1 may be made of a bridge metal.

The first touch routing line TL1 which is electrically connected to one (e.g., SUB1a) of the plurality of first sub sensor electrodes SUB1a and SUB1b included in the first sensor electrode SE1 may be disposed in the bridge metal layer BML. In other words, the first touch routing line TL1 may be made of the bridge metal.

The first touch routing line TL1 may extend to the first non-display area NDA1 by traversing the display area DA in the first direction without bypassing the second non-display area NDA2, and may be connected to the first touch pad TP1 in the pad area PA included in the first non-display area NDA1.

Accordingly, the first touch routing line TL1 may not be disposed on the second sloped surface SLP2 of the encapsulation layer 200, may traverse the display area DA to extend to the first non-display area NDA1, and may be disposed along the first sloped surface SLP1 of the encapsulation layer 200 to extend to the pad area PA.

Referring to FIG. 12, when the first touch routing line TL1 traverses the display area DA without bypassing the second non-display area NDA2, the first touch routing line TL1 may be disposed to avoid the light emitting area EA of each of the plurality of subpixels SP in the display area DA. Namely, the first touch routing line TL1 may not overlap the light emitting area EA of each of the plurality of subpixels SP and may overlap the bank BK. Accordingly, it is possible to design an internal touch routing structure without deterioration in light emission performance.

Referring to FIG. 12, not only the first touch routing line TL1 but also the first sensor electrode SE1 electrically connected to the first touch routing line TL1 may not overlap the light emitting area of each of the plurality of subpixels SP and may overlap the bank BK.

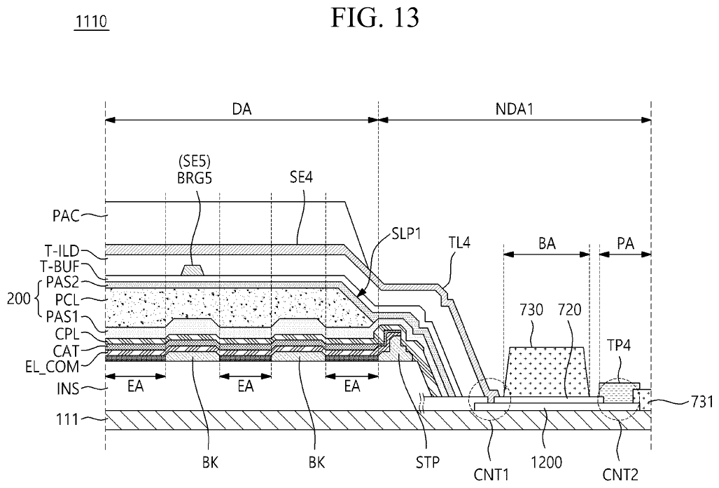

FIG. 13 is a cross-sectional view of a display panel 110 according to aspects of the present disclosure. FIG. 13 is a cross-sectional view for an area 1110 including the first non-display area NDA1 in FIG. 11. Hereinafter, description of the same structure as the vertical cross-sectional structure of FIG. 7 will be omitted, and description will be made mainly on differences from the vertical cross-sectional structure of FIG. 7.

Referring to FIG. 13, the substrate 111 may include the display area DA and the first non-display area NDA1 as an outer area of the display area DA in the first direction, and the first non-display area NDA1 may include the bending area BA and the pad area PA.

According to the example of FIG. 13, a fifth bridge BRG5 made of a bridge metal may be disposed on the encapsulation layer 200. The touch interlayer insulating layer T-ILD may be disposed on the fifth bridge BRG5. The fourth sensor electrode SE4 made of a sensor metal may be disposed on the touch interlayer insulating layer T-ILD.

Referring to FIG. 13, a portion of the fourth sensor electrode SE4 which extends to the first non-display area NDA1 may be the fourth touch routing line TL4. Accordingly, the fourth touch routing line TL4 may be made of a sensor metal.

The fourth touch routing line TL4 may descend along the first sloped surface SLP1 of the encapsulation layer 200 and extend to the pad area PA of the first non-display area NDA1.

The touch protection layer PAC may be disposed on the sensor electrodes SE including the fourth sensor electrode SE4 and the fifth sensor electrode SE5. The touch protection layer PAC may protect a touch sensor by blocking harmful environments from the outside, and may maintain the stability of the characteristics of the display device 100. For example, the touch protection layer PAC may be an organic layer. The touch protection layer PAC may be disposed to extend to the non-display area NDA.

The fourth touch routing line TL4 may extend along the first sloped surface SLP1 of the encapsulation layer 200, and may further extend over the stopper STP to be disposed along the outer side surface SIDE_INS of the insulating layer stack INS. The fourth touch routing line TLA may overlap the organic layer PCL of the encapsulation layer 200, and may overlap the stopper STP.

Referring to FIG. 13, the fourth touch pad TP4 may be disposed in the pad area PA. The fourth touch pad TP4 may be electrically connected to the fourth touch routing line TLA, and may be electrically connected to the touch sensing circuit 210.

Referring to FIG. 13, the bending area BA may include the bending layer 730 which is disposed on the substrate 111, and a touch connection pattern 1200 which is located under the bending layer 730 and electrically connects the fourth touch routing line TL4 and the fourth touch pad TP4. The insulating layer 720 may be disposed on the touch connection pattern 1200.

Referring to FIG. 13, the fourth touch routing line TL4 may not be disposed in the bending area BA. Accordingly, the fourth touch routing line TL4 may be electrically connected to the fourth touch pad TP4 through the touch connection pattern 1200 which is disposed in the bending area BA.

Referring to FIG. 13, the fourth touch routing line TL4 may be electrically connected to a portion of the touch connection pattern 1200 through a first contact hole CNT1 of the insulating layer 720. The fourth touch pad TP4 may be electrically connected to another portion of the touch connection pattern 1200 through a second contact hole CNT2 of the insulating layer 720.

Referring to FIG. 13, the touch connection pattern 1200 may include the same material as the source and drain areas of a transistor (e.g., DT or ST) disposed in the display area DA.

The touch connection pattern 1200 may be composed of a first touch connection pattern which includes the same material as the source and drain electrodes of a transistor (e.g., DT or ST) disposed in the display area DA and a second touch connection pattern which includes the same material as the gate electrode of the transistor (e.g., DT or ST) or the gate line GL.

The bending layer 730 may be disposed in the bending area BA, and may be disposed to cover the top of a portion of the touch connection pattern 1200. The bending layer 730 may prevent the touch connection pattern 1200 from being exposed to the outside in the bending area BA where the substrate 111 is bent, and may serve to protect the touch connection pattern 1200. An open hole which exposes the top of the bending layer 730 may be defined. That is to say, by removing inorganic layers (e.g., the first inorganic layer PAS1, the second inorganic layer PAS2 and the touch interlayer insulating layer T-ILD) which may be disposed on the bending layer 730, the open hole may be formed. In the case where an inorganic layer is disposed on the bending layer 730, when the bending area BA is bent, a crack may occur in the inorganic layer, and moisture, etc. may penetrate into the inorganic layer in which the crack has occurred. Therefore, the inorganic layers defined on the bending layer 730 are removed.

The pattern protection layer 731 may be disposed to surround the end of the touch connection pattern 1200 to protect the end of the touch connection pattern 1200 disposed at the edge of the first non-display area NDA1.

The bending layer 730 and the pattern protection layer 731 may be disposed at the same layer as the planarization layer included in the insulating layer stack INS, and may be made of the same material as the planarization layer.

For example, the bending layer 730 and the pattern protection layer 731 may be formed as an organic layer made of acryl resin, epoxy resin, phenolic resin, polyamide resin or polyimide resin

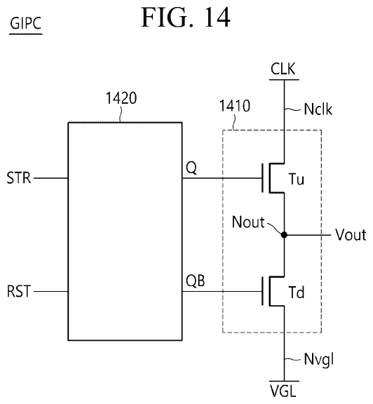

In the above, the stopper STP and the internal touch routing structure as an extremely narrow bezel structure were explained. Hereinafter, as another extremely narrow bezel structure, the gate driving circuit 130 disposed in the display area DA will be described with reference to FIGS. 14 to 21.

FIG. 14 shows a gate driving circuit 130 of a display device 110 according to aspects of the present disclosure.

Referring to FIG. 14, the display panel 110 according to the aspects of the present disclosure may include a gate-in-panel circuit GIPC which is configured to supply a gate signal to the plurality of subpixels SP and overlaps the organic layer PCL of the encapsulation layer 200.

Referring to FIG. 14, the gate-in-panel circuit GIPC is the gate driving circuit 130 which is embedded in the display panel 110. In other words, the gate-in-panel circuit GIPC may be the gate driving circuit 130 of a gate-in-panel type.

Referring to FIG. 14, the gate-in-panel circuit GIPC may include an output buffer 1410 which is configured to output a gate signal Vout and a control circuit 1420 which is configured to control the output buffer 1410.

The output buffer 1410 may include a pull-up transistor Tu connected between a clock node Nclk to which a clock signal CLK is inputted and an output node Nout from which the gate signal Vout is outputted, and a pull-down transistor Td connected between the output node Nout from which the gate signal Vout is outputted and a low voltage node Nvgl to which a second gate voltage VGL is inputted.

The gate signal Vout may be the scan signal SC of FIG. 2.

The output node Nout may be electrically connected to the gate line GL such as the scan line SCL.

The gate node of the pull-up transistor Tu may correspond to a Q node. Depending on the voltage level of the Q node, the pull-up transistor Tu may be turned on or turned off.

The gate node of the pull-down transistor Td may correspond to a QB node. Depending on the voltage level of the QB node, the pull-down transistor Td may be turned on or turned off.

The voltage level of the Q node and the voltage level of the QB node may be opposite to each other. Namely, when the voltage level of the Q node is a high level, the voltage level of the QB node may be a low level. When the voltage level of the Q node is a low level, the voltage level of the QB node may be a high level.

As the voltage level of the Q node and the voltage level of the QB node are opposite to each other, the on-off state of the pull-up transistor Tu and the on-off state of the pull-down transistor Td may be different from each other. That is to say, when the pull-up transistor Tu is in a turned-on state, the pull-down transistor Td may be in a turned-off state. When the pull-up transistor Tu is in a turned-off state, the pull-down transistor Td may be in a turned-on state.

The control circuit 1420 may be inputted with control signals such as a start signal STR and a reset signal RST, and may control the voltage level of the Q node and the voltage level of the QB node.

The control circuit 1420 may include a plurality of transistors.

When the voltage level of the Q node becomes a high level and the voltage level of the QB node becomes a low level by the control circuit 1420, the pull-up transistor Tu may be turned on, and the gate signal Vout which has the high level voltage of the clock signal CLK may be outputted to the output node Nout.

When the voltage level of the Q node becomes a low level and the voltage level of the QB node becomes a high level by the control circuit 1420, the pull-down transistor Td may be turned on, and the gate signal Vout which has the second gate voltage VGL corresponding to a low level voltage may be outputted to the output node Nout.

The transistors Tu and Td included in the output buffer 1410 and the plurality of transistors included in the control circuit 1420 are referred to as “gate driving transistors.” Meanwhile, the driving transistor DT and the scan transistor ST included in the subpixel circuit SPC are referred to as “pixel driving transistors.”

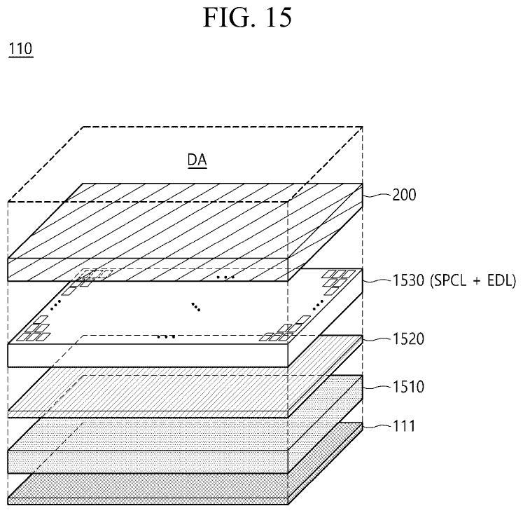

FIG. 15 shows the vertical structure of a display panel 110 according to aspects of the present disclosure when a gate-in-panel circuit GIPC is disposed over the entirety of the display area DA of the display panel 110.

Referring to FIG. 15, the display panel 110 according to the aspects of the present disclosure may include a substrate 111, a base circuit layer 1510, a pixel array layer 1530, and an encapsulation layer 200.

Referring to FIG. 15, the pixel array layer 1530, as a layer in which the plurality of subpixels SP are formed, may be located over the substrate 111. The pixel array layer 1530 may include the plurality of subpixels SP which are disposed in the display area DA where an image is displayed.

Referring to FIG. 15, the base circuit layer 1510 may be a layer in which the gate-in-panel circuit GIPC as the gate driving circuit 130 of a gate-in-panel type is formed, and may be located between the substrate 111 and the pixel array layer 1530. Namely, the base circuit layer 1510 may include the gate-in-panel circuit GIPC which is the gate driving circuit 130 of a gate-in-panel type.

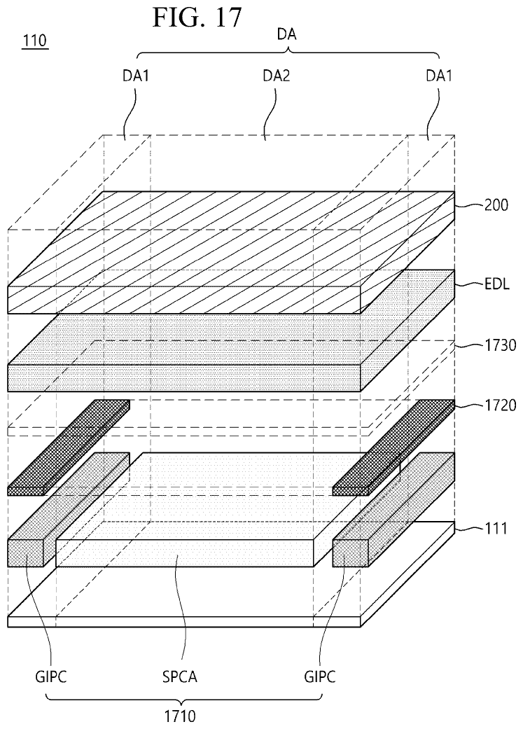

For example, the base circuit layer 1510 may include the gate-in-panel circuit GIPC which is disposed over the entirety of the display area DA (see FIGS. 15 and 16). For another example, the base circuit layer 1510 may include the gate-in-panel circuit GIPC which is disposed in at least one partial area of the display area DA (see FIGS. 17 to 21). In FIGS. 15 and 16, a case where the gate-in-panel circuit GIPC included in the base circuit layer 1510 is disposed over the entirety of the display area DA will be described as an example.

Referring to FIG. 15, the base circuit layer 1510 may be a layer in which at least two types of power lines to which at least two types of common pixel driving voltages to be supplied to the pixel array layer 1530 are applied are formed. That is to say, the base circuit layer 1510 may further include at least two types of power lines to which at least two types of common pixel driving voltages to be supplied to the pixel array layer 1530 are applied.

For example, the at least two types of common pixel driving voltages may include the first common driving voltage VDD and the second common driving voltage VSS which are supplied to the pixel array layer 1530. The at least two types of power lines may include the first common driving voltage line VDDL and the second common driving voltage line VSSL. The at least two types of power lines may be electrically connected to patterns (metals) in the pixel array layer 1530. In addition, the at least two types of power lines may include the patterns (the metals) in the pixel array layer 1530.

Referring to FIG. 15, the encapsulation layer 200 may be located on the pixel array layer 1530. The encapsulation layer 200 may prevent an organic layer disposed in the pixel array layer 1530 from being exposed to moisture or oxygen.

As described above, in the conventional display device, a gate driving circuit is connected to or formed in a non-display area (a bezel), but in the display device 100 according to the aspects of the present disclosure, as the gate-in-panel circuit GIPC is disposed in the display area DA, the size of the non-display area NDA may be significantly reduced.

In addition, in the conventional display device, various power lines are disposed in the non-display area NDA, but in the display device 100 according to the aspects of the present disclosure, as various power lines are disposed in the display area DA, the size of the non-display area NDA may be further reduced.

Moreover, even though the gate-in-panel circuit GIPC and/or the various power lines are disposed in the display area DA, since the gate-in-panel circuit GIPC and/or the various power lines are disposed to overlap the pixel array layer 1530 in the vertical direction, a space where the plurality of subpixels SP are disposed may not decrease. Accordingly, the size of the non-display area NDA may be reduced even without decreasing the aperture ratio of the display area DA of the display panel 110.

Referring to FIG. 15, the display panel 110 according to the aspects of the present disclosure may further include a shielding layer 1520 which is located between the base circuit layer 1510 and the pixel array layer 1530.

The shielding layer 1520 may shield the electric field between the base circuit layer 1510 and the pixel array layer 1530. Accordingly, the base circuit layer 1510 and the pixel array layer 1530 may not have an unwanted electrical effect on each other.

Referring to FIG. 15, to improve the shielding performance of the shielding layer 1520, the shielding layer 1520 may be electrically connected to a power line which is located in the base circuit layer 1510.

For example, the shielding layer 1520 may be electrically connected to a first power line among the at least two types of power lines which are located in the base circuit layer 1510. The first power line may be a power line to which the first common driving voltage VDD to be supplied to the pixel array layer 1530 is applied. Accordingly, the first power line may be electrically connected to the first common driving voltage line VDDL which is disposed in the pixel array layer 1530.

For another example, the shielding layer 1520 may be electrically connected to a second power line among the at least two types of power lines which are located in the base circuit layer 1510. The second power line may be a power line to which the second common driving voltage VSS to be supplied to the pixel array layer 1530 is applied. Accordingly, the second power line may be electrically connected to the second common driving voltage line VSSL which is disposed in the pixel array layer 1530.

Referring to FIG. 15, to improve the shielding performance of the shielding layer 1520, the shielding layer 1520 may be electrically connected to a metal which is located in the pixel array layer 1530.

For example, the shielding layer 1520 may be electrically connected to a first metal which is located in the pixel array layer 1530. The first metal may be a metal to which the first common driving voltage VDD is applied. The first metal as a metal to which the first common driving voltage VDD is applied may be the first common driving voltage line VDDL or a connection pattern which is connected to the first common driving voltage line VDDL.

For another example, the shielding layer 1520 may be electrically connected to a second metal which is located in the pixel array layer 1530. The second metal as a metal to which the second common driving voltage VSS is applied may be the second common driving voltage line VSSL or a connection pattern which is connected to the second common driving voltage line VSSL.

Referring to FIG. 15, the shielding layer 1520 may electrically connect a metal which is located in the pixel array layer 1530 and a metal which is located in the base circuit layer 1510.

For example, the shielding layer 1520 may electrically connect the first metal which is located in the pixel array layer 1530 and the first power line which is located in the base circuit layer 1510. The first metal may be a metal to which the first common driving voltage VDD is applied. The first metal as a metal to which the first common driving voltage VDD is applied may be the first common driving voltage line VDDL or a connection pattern which is connected to the first common driving voltage line VDDL. The first power line may be a power line to which the first common driving voltage VDD to be supplied to the pixel array layer 1530 is applied.

In the case of such an example, the shielding layer 1520 may be electrically connected to the light emitting element ED included in each of the plurality of subpixels SP and the source electrode or the drain electrode of one pixel driving transistor among the plurality of pixel driving transistors. Referring to the equivalent circuit of the subpixel SP shown in FIG. 2, the shielding layer 1520 may be electrically connected to the third node N3 of the driving transistor DT among the plurality of pixel driving transistors included in each of the plurality of subpixels SP. The third node N3 of the driving transistor DT may be a drain electrode or a source electrode.

For another example, the shielding layer 1520 may electrically connect the second metal which is located in the pixel array layer 1530 and the second power line which is located in the base circuit layer 1510. The second metal as a metal to which the second common driving voltage VSS is applied may be the second common driving voltage line VSSL or a connection pattern which is connected to the second common driving voltage line VSSL. The second power line may be a power line to which the second common driving voltage VSS to be supplied to the pixel array layer 1530 is applied.

In the case of such an example, the shielding layer 1520 may be electrically connected to the cathode CAT of the light emitting element ED included in each of the plurality of subpixels SP.

Referring to FIG. 15, the display panel 110 according to the aspects of the present disclosure may include the substrate 111, the pixel array layer 1530 which is located on the substrate 111 and in which the plurality of subpixels SP are disposed in the display area DA where an image is displayed, the base circuit layer 1510 which is located between the substrate 111 and the pixel array layer 1530, and the shielding layer 1520 which is located between the base circuit layer 1510 and the pixel array layer 1530.

The base circuit layer 1510 may include an organic layer which is disposed on a gate driving transistor included in the gate-in-panel circuit GIPC. The base circuit layer 1510 may include at least two types of power lines to which at least two types of common pixel driving voltages to be supplied to the pixel array layer 1530 are applied.

The shielding layer 1520 may electrically connect a metal which is disposed in the pixel array layer 1530 and a metal (a power line) which is disposed in the base circuit layer 1510.

The pixel array layer 1530 may include a subpixel circuit layer SPCL in which a plurality of subpixel circuits SPC are disposed and a light emitting element layer EDL in which a plurality of light emitting elements ED are disposed.

Referring to FIG. 15, the display panel 110 according to the aspects of the present disclosure may include the gate-in-panel circuit GIPC which is configured to supply a gate signal to the plurality of subpixels SP and overlaps the organic layer PCL of the encapsulation layer 200.

Referring to FIG. 15, the display panel 110 according to the aspects of the present disclosure may further include the base circuit layer 1510 on the substrate 111, the light emitting element layer EDL which is located on the base circuit layer 1510 and includes the plurality of light emitting elements DE included in the plurality of subpixels SP, and the shielding layer 1520 which is located between the base circuit layer 1510 and the light emitting element layer EDL.

Referring to FIG. 15, the subpixel circuit layer SPCL may be disposed between the shielding layer 1520 and the light emitting element layer EDL. The subpixel circuit layer SPCL and the light emitting element layer EDL may constitute the pixel array layer 1530.

Referring to FIG. 15, the base circuit layer 1510 may include the gate-in-panel circuit GIPC which is disposed in the display area DA.

FIG. 16 is a cross-sectional view of the display area DA of a display panel 110 according to aspects of the present disclosure.

Referring to FIG. 16, the display area DA of the display panel 110 may include the substrate 111, the base circuit layer 1510, the shielding layer 1520, the pixel array layer 1530, and the encapsulation layer 200.

The substrate 111 may include a first substrate 1601, an intermediate layer 1602, and a second substrate 1603. The intermediate layer 1602 may be disposed between the first substrate 1601 and the second substrate 1603. For example, at least one of the first substrate 1601 and the second substrate 1603 may be a substrate which includes polyimide (PI).

The base circuit layer 1510 may be located on the substrate 111.

The base circuit layer 1510 may include a lower shield metal 1605, a plurality of gate driving transistors Tg which constitute the gate driving circuit 130, and various insulating layers 1610, 1620 and 1621 for forming the plurality of gate driving transistors Tg.

Each of the plurality of gate driving transistors Tg may include a first active layer ACT1, a first source electrode A, a first drain electrode B and a first gate electrode C.

Various insulating layers 1611, 1612, 1620 and 1621 may include a first buffer layer 1610, a first gate insulating layer 1620, and a first interlayer insulating layer 1621.

The lower shield metal 1605 may be disposed on the substrate 111.

The first buffer layer 1610 may be disposed on the lower shield metal 1605.

The first buffer layer 1610 may include a multi-buffer layer 1611 and an active buffer layer 1612. The multi-buffer layer 1611 may be disposed on the lower shield metal 1605, and the active buffer layer 1612 may be disposed on the multi-buffer layer 1611.

The first active layer ACT1 may be disposed on the active buffer layer 1612.

The first gate insulating layer 1620 may be disposed on the first active layer ACT1, and the first gate electrode C may be disposed on the first gate insulating layer 1620 and may overlap a portion of the first active layer ACT1.

The portion of the first active layer ACT1 which overlaps the first gate electrode C may be a channel area.

The first interlayer insulating layer 1621 may be disposed on the first gate electrode C.

The first source electrode A and the first drain electrode B may be disposed on the first interlayer insulating layer 1621. The first source electrode A may be directly or indirectly connected to a first portion of the first active layer ACT1 through a first hole of the first interlayer insulating layer 1621. The first drain electrode B may be directly or indirectly connected to a second portion of the first active layer ACT1 through a second hole of the first interlayer insulating layer 1621. An area between the first portion and the second portion in the first active layer ACT1 may be a channel area.

A transistor included in the gate driving circuit 130 is referred to as a gate driving transistor Tg. Transistors included in the gate driving circuit 130 may include the pull-up transistor Tu and the pull-down transistor Td included in the output buffer 1410, and the plurality of transistors included in the control circuit 1420.

In the base circuit layer 1510, not only the gate driving circuit 130 but also a plurality of power lines PL1 to PLm to which a plurality of pixel driving voltages to be supplied to the pixel array layer 1530 are applied may be disposed. The plurality of power lines PL1 to PLm may include a second power line PL2 to which the second driving voltage VSS to be supplied to the pixel array layer 1530 is applied.

The base circuit layer 1510 may include an intermediate organic layer 1622 which is disposed on the plurality of gate driving transistors Tg included in the gate driving circuit 130.

The intermediate organic layer 1622 may be disposed on the plurality of gate driving transistors Tg and the plurality of power lines PL1 to PLm which are included in the gate driving circuit 130, to reduce a step in the base circuit layer 1510.

In addition, the intermediate organic layer 1622 may reduce unnecessary parasitic capacitance between a metal disposed on the base circuit layer 1510 and a metal disposed in the base circuit layer 1510.

The top surface of the intermediate organic layer 1622 may have a smaller step than the bottom surface of the intermediate organic layer 1622.

The intermediate organic layer 1622 may have a thickness T thicker than the thickness of the first gate insulating layer 1620 between the first gate electrode C and the first active layer ACT1 of each of the plurality of gate driving transistors Tg.

The shielding layer 1520 may be disposed on the base circuit layer 1510, and the pixel array layer 1530 may be disposed on the shielding layer 1520. That is to say, the shielding layer 1520 may be located between the base circuit layer 1510 and the pixel array layer 1530. Accordingly, the electric field between the base circuit layer 1510 and the pixel array layer 1530 may be shielded.

The shielding layer 1520 may be electrically connected to the second power line PL2, which is one of the at least two types of power lines PL1 to PLm, through a hole of the intermediate organic layer 1622. The second power line PL2 may be a power line to which the second driving voltage VSS is applied.

The plurality of power lines PL1 to PLm disposed in the base circuit layer 1510 may include the same material as the first source electrode A and the first drain electrode B of the gate driving transistor Tg.

The pixel array layer 1530 may include a plurality of pixel driving transistors Tp, a plurality of storage capacitors Cst and a plurality of light emitting elements ED.

The pixel array layer 1530 may include a second buffer layer 1630, a second interlayer insulating layer 1631, a third interlayer insulating layer 1632, a second gate insulating layer 1633, a fourth interlayer insulating layer 1634, a planarization layer 1640, a bank BK, and a spacer SPCR. The planarization layer 1640 may include a first planarization layer 1641 and a second planarization layer 1642.

Each of the plurality of pixel driving transistors Tp may include a second active layer ACT2, a second source electrode D, a second drain electrode E and a second gate electrode F.

Each of the plurality of storage capacitors Cst may include a first capacitor electrode PLT1 and a second capacitor electrode PLT2.

Each of the plurality of light emitting elements ED may include an anode AND1 or AND2, an element intermediate layer EL and a cathode CAT.

The second buffer layer 1630 may be disposed on the shielding layer 1520.

The first capacitor electrode PLT1 may be disposed on the second buffer layer 1630, the second interlayer insulating layer 1631 may be disposed on the first capacitor electrode PLT1, and the second capacitor electrode PLT2 may be disposed on the second interlayer insulating layer 1631.

The first capacitor electrode PLT1 and the second capacitor electrode PLT2 may overlap each other to constitute the storage capacitor Cst.

The third interlayer insulating layer 1632 may be disposed on the second capacitor electrode PLT2.

The second active layer ACT2 may be disposed on the third interlayer insulating layer 1632.

The second gate insulating layer 1633 may be disposed on the second active layer ACT2, and the second gate electrode F may be disposed on the second gate insulating layer 1633. The second gate electrode F may overlap a portion of the second active layer ACT2. The portion of the second active layer ACT2 which overlaps the second gate electrode F may be a channel area.

The fourth interlayer insulating layer 1634 may be disposed on the second gate electrode F, and the second source electrode E and the second drain electrode D may be disposed on the fourth interlayer insulating layer 1634.

The second source electrode E may be electrically connected to a first portion of the second active layer ACT2 through a first hole of the fourth interlayer insulating layer 1634, and the second drain electrode D may be electrically connected to a second portion of the second active layer ACT2 through a second hole of the fourth interlayer insulating layer 1634. An area between the first portion and the second portion in the second active layer ACT2 may be a channel area.

The planarization layer 1640 may be disposed on the second source electrode E and the second drain electrode D. The anode AND1 or AND2 may be disposed on the planarization layer 1640, and may be electrically connected to the second source electrode E or the second drain electrode D through a hole of the planarization layer 1640.

When the planarization layer 1640 includes the first planarization layer 1641 and the second planarization layer 1642, the first planarization layer 1641 may be disposed on the second source electrode E and the second drain electrode D, and a relay electrode RE may be disposed on the first planarization layer 1641 and be electrically connected to the second source electrode E or the second drain electrode D through a hole of the first planarization layer 1641. The second planarization layer 1642 may be disposed on the relay electrode RE. The anode AND1 or AND2 may be disposed on the second planarization layer 1642, and may be electrically connected to the relay electrode RE through a hole of the second planarization layer 1642.

When the subpixel SP has the structure shown in FIG. 2, the pixel driving transistor Tp shown in FIG. 16 includes the second source electrode E which is electrically connected to the anode AND1 or AND2 of the light emitting element ED. Therefore, the pixel driving transistor Tp shown in FIG. 16 may be the driving transistor DT in FIG. 2.

The bank BK may be disposed on the anodes AND1 and AND2, and may have openings corresponding to the light emitting areas EA.

The element intermediate layer EL may be disposed on the bank BK, and may contact the anodes AND1 and AND2 at the openings of the bank BK. Spacers SPCR may be located on the bank BK at some points (e.g., points where the spacers SPCR overlap the anodes AND1 and AND2 or boundary points of the light emitting areas EA).

The cathode CAT may be disposed on the element intermediate layer EL.

Areas where the anodes AND1 and AND2, the element intermediate layer EL and the cathode CAT overlap may form the light emitting areas EA1 and EA2. In FIG. 16, a common intermediate layer EL_COM is shown by combining the first common intermediate layer COM1 and the second common intermediate layer COM2 included in the element intermediate layer EL, and the first light emitting layer EML1 and the second light emitting layer EML2 are omitted. The encapsulation layer 200 may be disposed on the pixel array layer 1530.

The encapsulation layer 200 may include a first inorganic layer PAS1, an organic layer PCL and a second inorganic layer PAS2. For example, the first inorganic layer PAS1 and the second inorganic layer PAS2 may be inorganic layers, and the organic layer PCL may be an organic layer.

A first metal GA in the base circuit layer 1510 and a second metal GB in the pixel array layer 1530 may be electrically connected through an opening of the shielding layer 1520.

In addition, the first metal GA in the base circuit layer 1510 and the second metal GB in the pixel array layer 1530 may be electrically connected through a connection metal GCP which is separated from the shielding layer 1520. The connection metal GCP may include the same material as the shielding layer 1520, and may be located at the same layer as the shielding layer 1520. The connection metal GCP is also referred to as a gate link line GCP.

The second metal GB in the pixel array layer 1530 may be disposed on the second gate insulating layer 1633. The second metal GB may include the same material as the second gate electrode F, and may be located at the same layer as the second gate electrode F.

The first metal GA in the base circuit layer 1510 may be disposed on the first interlayer insulating layer 1621. The second metal GB in the pixel array layer 1530 may be electrically connected to the first metal GA in the base circuit layer 1510 through holes of the second buffer layer 1630, the second interlayer insulating layer 1631, the third interlayer insulating layer 1632, the second gate insulating layer 1633, the shielding layer 1520 and the organic layer 1622.

The first metal GA in the base circuit layer 1510 may be a metal which electrically corresponds to output nodes Nout1a, Nout1b, Nout1 and Nout2 in the base circuit layer 1510 of FIGS. 11 and 12.

The second metal GB in the pixel array layer 1530 may be a metal which electrically corresponds to input nodes Nin1 and Nin2 in the pixel array layer 1530 of FIGS. 11 and 12. For example, the second metal GB in the pixel array layer 1530 may be one among a first scan line SCL1, a second scan line SCL2, a third scan line SCL3, a first light emission control line EML1 and a second light emission control line EML2.

Referring to FIG. 16, the base circuit layer 1510 may include the gate driving transistor Tg which includes the first active layer ACT1, and the pixel array layer 1530 may include the pixel driving transistor Tp which includes the second active layer ACT2.

The first active layer ACT1 and the second active layer ACT2 may include different semiconductor materials. For example, the first active layer ACT1 may include a silicon-based semiconductor material. The second active layer ACT2 may include an oxide-based semiconductor material.

For example, the silicon-based semiconductor material may include amorphous silicon (a-Si) or low-temperature polycrystalline silicon (LTPS). For example, the oxide-based semiconductor material may include indium gallium zinc oxide (IGZO), indium gallium zinc tin oxide (IGZTO), zinc oxide (ZnO), cadmium oxide (CdO), indium oxide (InO), zinc tin oxide (ZTO), zinc indium tin oxide (ZITO), etc., or may also include low-temperature polycrystalline oxide (LTPO).

The first active layer ACT1 and/or the second active layer ACT2 may be a single layer or a multilayer. For example, when the first active layer ACT1 and/or the second active layer ACT2 is a multilayer, the multilayer may be composed of the same semiconductor material or may be composed of at least two different semiconductor materials.

Referring to FIG. 16, the encapsulation layer 200 and the cathode CAT may overlap the gate driving circuit 130.

Referring to FIG. 16, the cathode CAT may be an electrode capable of transmitting light. The anodes AND1 and AND2 may be reflective electrodes, and may overlap at least a portion of the gate driving circuit 130. Accordingly, the display panel 110 may have a structure capable of top emission.

Referring to FIG. 16, the second driving voltage VSS may be applied to the shielding layer 1510 included in the display panel 110 according to the aspects of the present disclosure.

Referring to FIG. 16, the shielding layer 1520 may be electrically connected to the cathode CAT to which the second driving voltage VSS, a type of pixel driving voltage, is applied.

The cathode CAT and the shielding layer 1520 may be electrically connected through a first connection pattern CP1 and a second connection pattern CP2. The first connection pattern CP1 may be a metal which is disposed on the fourth interlayer insulating layer 1634. The first connection pattern CP1 may be connected to the shielding layer 1520 through holes of the second buffer layer 1630, the second interlayer insulating layer 1631, the third interlayer insulating layer 1632, the second gate insulating layer 1633 and the fourth interlayer insulating layer 1634. The second connection pattern CP2 may be a metal which is disposed on the first planarization layer 1641. The second connection pattern CP2 may be connected to the first connection pattern CP1 through a hole of the first planarization layer 1641.

The first connection pattern CP1 and the second connection pattern CP2 may be electrically connected to the second driving voltage line VSSL disposed in the pixel array layer 1530. At least one of the first connection pattern CP1 and the second connection pattern CP2 may be the second driving voltage line VSSL disposed in the pixel array layer 1530.

The cathode CAT in the pixel array layer 1530 and the second power line PL2 in the base circuit layer 1510 may be electrically connected through the first and second connection patterns CP1 and CP2 and the shielding layer 1520.

Referring to FIG. 16, the second common driving voltage line VSSL may be disposed on the substrate 111, and may supply the second common pixel driving voltage VSS to the cathode CAT.

The second common driving voltage line VSSL may be disposed in the display area DA. The cathode CAT may be electrically connected to the second common driving voltage line VSSL in the display area DA. Accordingly, the size of the non-display area NDA may be further reduced.

Referring to FIG. 16, a voltage with a predetermined voltage level may be applied to the shielding layer 1520. For example, the second common pixel driving voltage VSS may be applied to the shielding layer 1520. To this end, the shielding layer 1520 may be electrically connected to the cathode CAT, and may be electrically connected to the second common driving voltage line VSSL.

Referring to FIG. 16, the bank BK may be located on the insulating layer stack INS, and may have a first opening and a second opening.

The first anode AND1 and the second anode AND2 may be located on the insulating layer stack INS, and may overlap the first opening and the second opening, respectively.

The first common intermediate layer COM1 may be disposed in common on the first anode AND1 and the second anode AND2.

The first light emitting layer EML1 and the second light emitting layer EML2 may be located on the first common intermediate layer COM1, and may overlap the first anode AND1 and the second anode AND2.

The second common intermediate layer COM2 may be disposed in common on the first light emitting layer EML1 and the second light emitting layer EML2.

In FIG. 16, the common intermediate layer EL_COM including the first common intermediate layer COM1 and the second common intermediate layer COM2 is shown, and the first light emitting layer EML1 and the second light emitting layer EML2 are omitted.

Referring to FIG. 16, the cathode CAT may be located on the common intermediate layer EL_COM.

Referring to FIG. 16, the cathode CAT and the second common driving voltage line VSSL may be electrically connected through holes penetrating at least portions of the common intermediate layer EL_COM including the first common intermediate layer COM1 and the second common intermediate layer COM2, the bank BK and the insulating layer stack INS.

The subpixel circuit layer SPCL may be located between the shielding layer 1520 and the light emitting element layer EDL, and may include a plurality of subpixel circuits SPC for driving the plurality of light emitting elements ED.

Referring to FIG. 16, the gate link line GCP may connect the gate-in-panel circuit GIPC disposed in the base circuit layer 1520 and the plurality of subpixel circuits SPC. The gate link line GCP may overlap the organic layer PCL of the encapsulation layer 200.

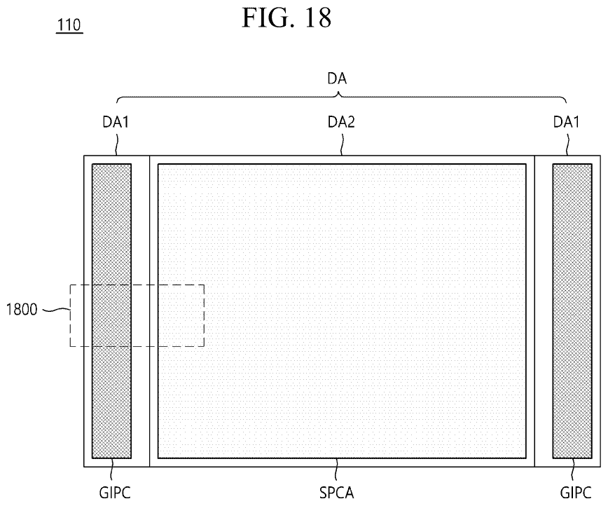

FIGS. 17 and 18 show the vertical structure and the planar structure of a display panel 110 according to aspects of the present disclosure when a gate-in-panel circuit GIPC is disposed in a part of the display area DA of the display panel 110.

Referring to FIGS. 17 and 18, the display area DA of the display panel 110 may include a first display area DA1 and a second display area DA2. As shown in FIGS. 17 and 18, the first display area DA1 may be disposed on both one side and the other side of the second display area DA2. Unlike this, the first display area DA1 may be disposed on only one of one side and the other side of the second display area DA2.

Referring to FIGS. 17 and 18, the display panel 110 according to the aspects of the present disclosure may include a substrate 111, a base circuit layer 1710, a light emitting element layer EDL, and an encapsulation layer 200.

Referring to FIGS. 17 and 18, the base circuit layer 1710 may be located on the substrate 111 and may include a gate-in-panel circuit GIPC. The base circuit layer 1710 may further include, in addition to the gate-in-panel circuit GIPC, a subpixel circuit array SPCA including a plurality of subpixel circuits SPC for driving a plurality of light emitting elements ED.

Referring to FIGS. 17 and 18, the light emitting element layer EDL may be located over the base circuit layer 1710. The plurality of light emitting elements ED may be disposed in the light emitting element layer EDL.

Referring to FIGS. 17 and 18, the gate-in-panel circuit GIPC may be disposed in the first display area DA1, and the subpixel circuit array SPCA may be disposed in the second display area DA2. In the first display area DA1, the gate-in-panel circuit GIPC is may overlap the organic layer PCL.

Referring to FIGS. 17 and 18, the plurality of light emitting elements ED disposed in the light emitting element layer EDL may include at least two first light emitting elements ED disposed in the first display area DA1 and at least two second light emitting elements ED disposed in the second display area DA2.

Referring to FIGS. 17 and 18, at least some of the at least two first light emitting elements ED disposed in the first display area DA1 may overlap at least a portion of the gate-in-panel circuit GIPC. At least some of the at least two second light emitting elements ED disposed in the second display area DA2 may overlap at least a portion of the subpixel circuit array SPCA.

Referring to FIG. 17, the display panel 110 according to the aspects of the present disclosure may further include an anode extension link layer 1730 between the base circuit layer 1710 and the light emitting element layer EDL.

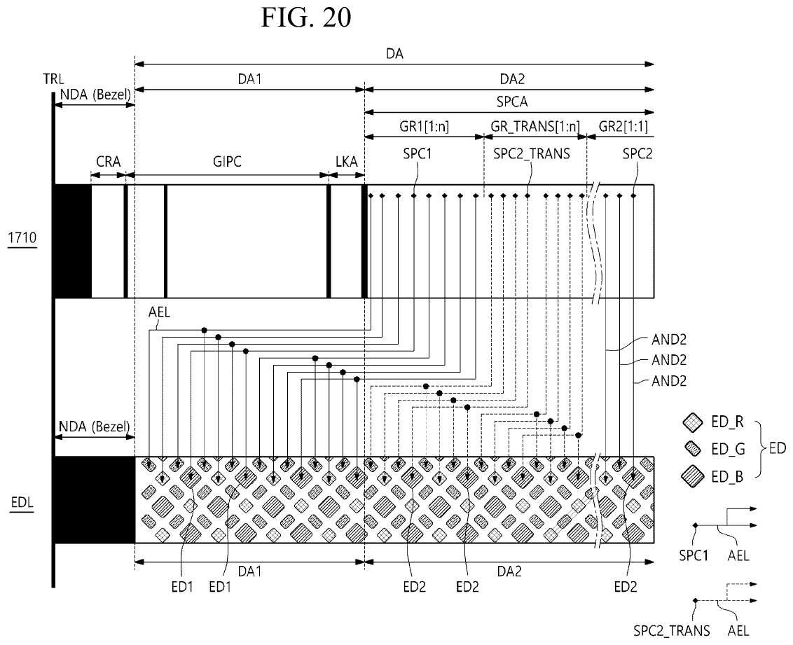

In the anode extension link layer 1730, there may be disposed an anode extension link (also referred to as an extension link or a connection pattern shown as AEL of FIG. 20). The anode extension link may electrically connect the subpixel circuits SPC included in the subpixel circuit array SPCA disposed in the second display area DA2 and the first light emitting elements ED disposed in the first display area DA1.

As described above, in the display panel 110 according to the aspects of the present disclosure, as the gate-in-panel circuit GIPC is not disposed in the non-display area NDA but is disposed in the first display area DA1 included in the display area DA, a bezel corresponding to the non-display area NDA may be made smaller.

Referring to FIG. 17, the display panel 110 according to the aspects of the present disclosure may further include a shielding layer 1720 which is located between the gate-in-panel circuit GIPC included in the base circuit layer 1710 and the light emitting element layer EDL.

Referring to FIG. 17, the shielding layer 1720 may be disposed in the first display area DA1, and may be located between the anode extension link layer 1730 and the gate-in-panel circuit GIPC.

At least a portion of the shielding layer 1720 may overlap the extension link (the anode extension link) disposed in the anode extension link layer 1730 and the gate-in-panel circuit GIPC. Accordingly, the anode extension link AEL electrically connected to the anode AND and the gate-in-panel circuit GIPC may not exert an unwanted electrical influence on each other. Due to this fact, image quality may be improved.

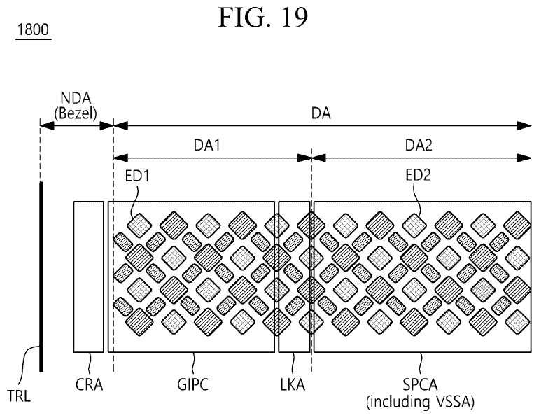

FIG. 19 is a plan view of a partial area 1800 of the display panel 110 of FIG. 18.

Referring to FIG. 19, the display panel 110 may include the display area DA and the non-display area NDA, and the display area DA may include the first display area DA1 and the second display area DA2. The non-display area NDA is also referred to as a bezel.

Referring to FIG. 19, the first display area DA1 may be located between the non-display area NDA and the second display area DA2.

Referring to FIG. 19, the display area DA may include a plurality of light emitting elements ED. For example, the plurality of light emitting elements ED may include a red light emitting element ED_R for emitting red light, a green light emitting element ED_G for emitting green light, and a blue light emitting element ED_B for emitting blue light.

Referring to FIG. 19, the plurality of light emitting elements ED disposed in the display area DA may include a plurality of first light emitting elements ED1 disposed in the first display area DA1 and a plurality of second light emitting elements ED2 disposed in the second display area DA2.

Referring to FIG. 19, the subpixel circuit array SPCA may be disposed in the second display area DA2. The subpixel circuit array SPCA may include the plurality of subpixel circuits SPC.

The plurality of subpixel circuits SPC may include at least one first subpixel circuit SPC for driving the plurality of first light emitting elements ED1 disposed in the first display area DA1 and a plurality of second subpixel circuits SPC for driving the plurality of second light emitting elements ED2 disposed in the second display area DA2.

The entirety or a part of the gate-in-panel circuit GIPC may be disposed in the first display area DA1.

In other words, the plurality of light emitting elements ED may include the first light emitting elements ED1 which are disposed in the first display area DA1 and overlap at least a portion of the gate-in-panel circuit GIPC, and the second light emitting elements ED2 which are disposed in the second display area DA2 and overlap at least a portion of the subpixel circuit array SPCA.

Referring to FIG. 19, the plurality of subpixel circuits SPC included in the subpixel circuit array SPCA may include a first subpixel circuit SPC which is configured to drive the first light emitting element ED1 disposed in the first display area DA1 and is disposed in the second display area DA2, and at least two second subpixel circuits SPC which are configured to drive the second light emitting elements ED2 disposed in the second display area DA2 and are disposed in the second display area DA2.

Referring to FIG. 19, the display panel 110 according to the aspects of the present disclosure may include a link area LKA where links for transferring various gate signals outputted from the gate-in-panel circuit GIPC to the subpixel circuit array SPCA are disposed. For example, the links disposed in the link area LKA may electrically connect the output points of the gate-in-panel circuit GIPC and gate lines GL. In the case where the output points of the gate-in-panel circuit GIPC are a first metal layer and the gate lines GL are a second metal layer different from the first metal layer, the links may include a jumping metal which connects the first metal layer and the second metal layer to each other.

Referring to FIG. 19, the link area LKA may be located between the gate-in-panel circuit GIPC and the subpixel circuit array SPCA. The link area LKA may be included in the first display area DA1.

Referring to FIG. 19, the display panel 110 according to the aspects of the present disclosure may include a crack management area CRA where a crack detection line and/or a crack stopper pattern is disposed.

For example, referring to FIG. 19, the crack management area CRA may be included in the non-display area NDA. In this case, the crack detection line and/or the crack stopper pattern may not overlap the first light emitting element ED1 disposed in the first display area DA1.

For another example, the crack management area CRA may be included in the first display area DA1. In this case, the crack detection line and/or the crack stopper pattern may overlap the first light emitting element ED1 disposed in the first display area DA1.

Referring to FIG. 19, the display panel 110 according to the aspects of the present disclosure may further include a base voltage line area VSSA where the base voltage line VSSL is disposed.

Referring to FIG. 19, in the display panel 110 according to the aspects of the present disclosure, the base voltage line VSSL may be disposed in the display area DA. For example, the base voltage line VSSL may be disposed in at least one of the first display area DA1 and the second display area DA2 included in the display area DA. Accordingly, the cathode CAT may be electrically connected to the base voltage line VSSL in at least one of the first display area DA1 and the second display area DA2 included in the display area DA.

Accordingly, the base voltage line area VSSA may not exist in the non-display area NDA. Due to this fact, the size of the bezel between a trimming line TRL and the display area DA may become smaller.

FIG. 20 shows the correspondence relationship between subpixel circuits SPC1, SPC2_TRANS and SPC2 and light emitting elements ED1 and ED2 in a display panel 110 according to aspects of the present disclosure.

Referring to FIG. 20, in terms of a planar structure, the display panel 110 may include a display area DA and a non-display area NDA. The display area DA may include a first display area DA1 and a second display area DA2.

Referring to FIG. 20, in terms of a vertical structure, the display panel 110 may include a base circuit layer 1710 and a light emitting element layer EDL.

Referring to FIG. 20, in the base circuit layer 1710, the entirety or most of a gate-in-panel circuit GIPC may be disposed in the first display area DA1. In the base circuit layer 1710, a subpixel circuit array SPCA including subpixel circuits SPC1, SPC2_TRANS and SPC2 may be disposed in the second display area DA2.

Referring to FIG. 20, in the base circuit layer 1710, a link area LKA may be disposed in the first display area DA1 or the second display area DA2, or may be disposed over the first display area DA1 and the second display area DA1.

Referring to FIG. 20, a plurality of light emitting elements ED disposed in the light emitting element layer EDL may be disposed in the display area DA. The plurality of light emitting elements ED disposed in the light emitting element layer EDL may include a plurality of first light emitting elements ED1 which are disposed in the first display area DA1 and a plurality of second light emitting elements ED2 which are disposed in the second display area DA2.

Referring to FIG. 20, a plurality of subpixel circuits SPC included in the subpixel circuit array SPCA may include at least one first subpixel circuit SPC1 which is configured to drive the plurality of first light emitting elements ED1 disposed in the first display area DA1, and a plurality of second subpixel circuits SPC2 which are configured to drive the plurality of second light emitting elements ED2 disposed in the second display area DA2.

Referring to FIG. 20, the plurality of subpixel circuits SPC included in the subpixel circuit array SPCA may be classified into a first group GR1[1:n], a transition group GR_TRANS[1:n] and a second group GR2[1:1].

Referring to FIG. 20, the second group GR2[1:1] may include a plurality of second subpixel circuits SPC2. The second group GR2[1:1] may drive one second light emitting element ED2 disposed in the second display area DA2 in a “one-to-one (1:1) driving method.”

Each of the plurality of second subpixel circuits SPC2 included in the second group GR2[1:1] may drive one second light emitting element ED2 disposed in the second display area DA2. In other words, one second subpixel circuit SPC2 included in the second group GR2[1:1] may drive one second light emitting element ED2 disposed in the second display area DA2. Accordingly, the second anode AND2 of one second light emitting element ED2 may be connected one to one to one second subpixel circuit SPC2.

Referring to FIG. 20, the first group GR1[1:n] may include a plurality of first subpixel circuits SPC1. The first group GR1[1:n] may drive at least two first light emitting elements ED1 disposed in the first display area DA1 in a “one-to-many driving method or a common driving method.”

Each of the plurality of first subpixel circuits SPC1 included in the first group GR1[1:n] may drive together at least two first light emitting elements ED1 disposed in the first display area DA1. Namely, one first subpixel circuit SPC1 included in the first group GR1[1:n] may drive together at least two first light emitting elements ED1 disposed in the first display area DA1.

For example, as shown in FIG. 20, one first subpixel circuit SPC1 included in the first group GR1[1:n] may drive together two first light emitting elements ED1 disposed in the first display area DA1.

Referring to FIG. 20, in order for one first subpixel circuit SPC1 disposed in the second display area DA2 to drive together at least two first light emitting elements ED1 disposed in the first display area DA1, the display panel 110 according to the aspects of the present disclosure may further include an anode extension link AEL for connecting one first subpixel circuit SPC1 disposed in the second display area DA2 to at least two first light emitting element ED1 disposed in the first display area DA1.

The anode extension link AEL may be disposed in the anode extension link layer 1730 located between the base circuit layer 1710 and the light emitting element layer EDL. Accordingly, the anode extension link AEL may include a metal (an anode extension link layer metal) located between the base circuit layer 1710 and the light emitting element layer EDL.

Referring to FIG. 20, some of the plurality of first subpixel circuits SPC1 included in the first group GR1[1:n] may be connected to one scan line SCL, and may be supplied with a scan signal SC from the one scan line SCL.

Referring to FIG. 20, the at least two first light emitting elements ED1 driven together by one first subpixel circuit SPC1 included in the first group GR1[1:n] may emit light of the same color.

Referring to FIG. 20, one first subpixel circuit SPC1 included in the first group GR1[1:n] may be supplied with the scan signal SC and a data signal VDATA, and may drive together at least two first light emitting elements ED1 on the basis of the scan signal SC and the data signal VDATA.

Referring to FIG. 20, the transition group GR_TRANS[1:n] may include a plurality of transition subpixel circuits SPC2_TRANS. The transition group GR_TRANS[1:n] may also drive at least two second light emitting elements ED2 disposed in the second display area DA2 in a “one-to-many driving method or a common driving method.”

Each of the plurality of transition subpixel circuits SPC2_TRANS included in the transition group GR_TRANS[1:n] may drive at least two second light emitting elements ED2 disposed in the second display area DA2. Namely, one transition subpixel circuit SPC2_TRANS included in the transition group GR_TRANS[1:n] may drive at least two second light emitting elements ED2 disposed in the second display area DA2.

Referring to FIG. 20, at least two second light emitting elements ED2 driven together by one transition subpixel circuit SPC2_TRANS according to the one-to-many driving method may be adjacent light emitting elements ED which emit light of the same color.

As at least two second light emitting elements ED2 driven together by one transition subpixel circuit SPC2_TRANS according to the one-to-many driving method are configured with light emitting elements ED which emit light of the same color and are disposed adjacent to each other, the at least two second light emitting elements ED2 exhibit similar light emission characteristics. Therefore, image quality by one-to-many driving may be at the same level as image quality by one-to-one driving.

Referring to FIG. 20, in order for one transition subpixel circuit SPC2_TRANS disposed in the second display area DA2 to drive together at least two second light emitting elements ED2 disposed in the second display area DA2, the display panel 110 according to the aspects of the present disclosure may further include a transition anode extension link AEL for connecting one transition subpixel circuit SPC2_TRANS disposed in the second display area DA2 to at least two second light emitting elements ED2 disposed in the second display area DA2.

Referring to FIG. 20, the second light emitting elements ED2 driven by the transition subpixel circuits SPC2_TRANS included in the transition group GR_TRANS[1:n] may be disposed adjacent to the first light emitting elements ED1 driven by the first subpixel circuits SPC1 included in the first group GR1[1:n].

Referring to FIG. 20, the second light emitting elements ED2 driven by the transition subpixel circuits SPC2_TRANS included in the transition group GR_TRANS[1:n] may be disposed between the first light emitting elements ED1 driven by the first subpixel circuits SPC1 included in the first group GR1[1:n] and the second light emitting elements ED2 driven by the second subpixel circuits SPC2 included in the second group GR2[1:1].

Referring to FIG. 20, the transition group GR_TRANS[1:n] may be disposed between the first group GR1[1:n] and the second group GR2[1:1].

As described above, the extension link AEL may connect the first subpixel circuit SPC1 disposed in the second display area DA2 to the first light emitting element ED1 disposed in the first display area DA1. At least a portion of the extension link AEL may overlap at least a portion of the gate-in-panel circuit GIPC, and the extension link AEL may overlap the organic layer PCL.

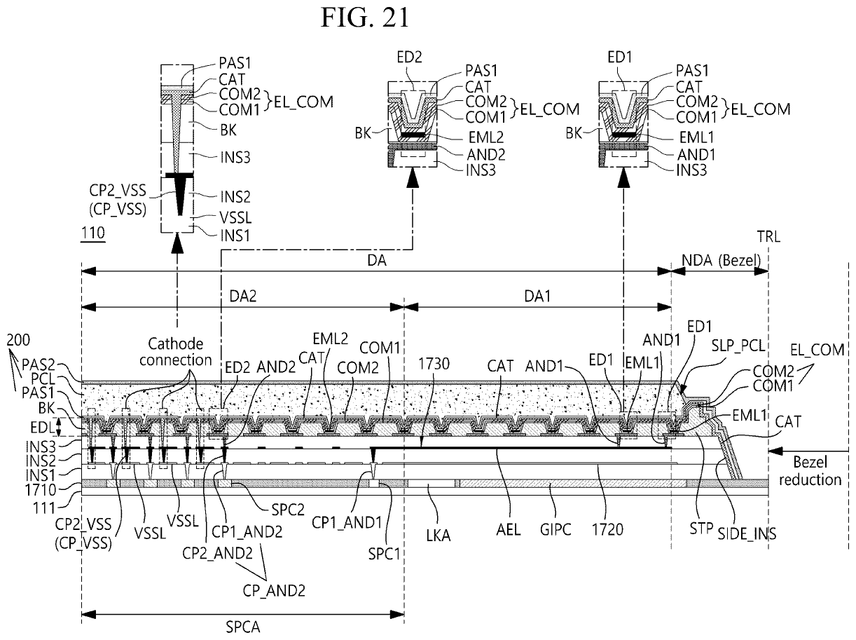

FIG. 21 is a cross-sectional view showing the vertical structure of a display panel 110 according to aspects of the present disclosure.

Referring to FIG. 21, the display panel 110 according to the aspects of the present disclosure may include a display area DA and a non-display area NDA. The display area DA may include a first display area DA1 and a second display area DA2. The first display area DA1 may be located between the second display area DA2 and the non-display area NDA.

Referring to FIG. 21, the display panel 110 according to the aspects of the present disclosure may include a substrate 111, a base circuit layer 1710 on the substrate 111, and a light emitting element layer EDL on the base circuit layer 1710.

The display panel 110 according to the aspects of the present disclosure may further include at least one insulating layer disposed between the base circuit layer 1710 and the light emitting element layer EDL.

For example, as shown in FIG. 21, first to third insulating layers INS1, INS2 and INS3 may be disposed between the base circuit layer 1710 and the light emitting element layer EDL. For example, the first insulating layer INS1 may be an inorganic layer or an organic layer. The second insulating layer INS2 and the third insulating layer INS3 may serve as planarization layers, and may be organic layers.

Referring to FIG. 21, in the base circuit layer 1710, a subpixel circuit array SPCA, a link area LKA and a gate-in-panel circuit GIPC may be disposed.

The subpixel circuit array SPCA may be disposed in the second display area DA2, the link area LKA may be disposed in the first display area DA1, and the gate-in-panel circuit GIPC may be disposed in the first display area DA1.

Referring to FIG. 21, a plurality of light emitting elements ED may be disposed in the light emitting element layer EDL. The plurality of light emitting elements ED disposed in the light emitting element layer EDL may include a plurality of first light emitting elements ED1 which are disposed in the first display area DA1 and a plurality of second light emitting elements ED2 which are disposed in the second display area DA2.

At least two first light emitting elements ED1 disposed in the first display area DA1 may be driven in a one-to-many driving method (a common driving method) by at least one first subpixel circuit SPC1 among a plurality of subpixel circuits SPC included in the subpixel circuit array SPCA.

Most of the plurality of second light emitting elements ED2 disposed in the second display area DA2 may be driven in a one-to-one driving method by second subpixel circuits SPC2 among the plurality of subpixel circuits SPC included in the subpixel circuit array SPCA.

Some of the plurality of second light emitting elements ED2 disposed in the second display area DA2 may be driven in the common driving method by transition subpixel circuits SPC2_TRANS among the plurality of subpixel circuits SPC included in the subpixel circuit array SPCA (see FIG. 7).

Referring to FIG. 21, the light emitting element layer EDL may include at least two first anodes AND1 disposed in the first display area DA1, and at least two first light emitting layers EML1 disposed in the first display area DA1 and located on the at least two first anodes AND1, respectively.

Referring to FIG. 21, the light emitting element layer EDL may include at least two second anodes AND2 disposed in the second display area DA2, and at least two second light emitting layers EML2 disposed in the second display area DA2 and located on the at least two second anodes AND2, respectively.

Referring to FIG. 21, the light emitting element layer EDL may include a cathode CAT which is disposed over the first display area DA1 and the second display area DA2 and is located on the at least two first light emitting layers EML1 and the at least two second light emitting layers EML2. A base voltage VSS, which is a second driving voltage, may be applied to the cathode CAT.

Referring to FIG. 21, at least two first light emitting elements ED1 may be configured in the first display area DA1 by the at least two first anodes AND1, the at least two first light emitting layers EML1 and the cathode CAT.

Referring to FIG. 21, at least two second light emitting elements ED2 may be configured in the second display area DA2 by the at least two second anodes AND2, the at least two second light emitting layers EML2 and the cathode CAT.

Referring to FIG. 21, a first common intermediate layer COM1 and a second common intermediate layer COM2 may be disposed over the entire display area DA. The first common intermediate layer COM1 may be disposed over the entire display area DA while being located between the anodes AND1 and AND2 and the light emitting layers EML1 and EML2. The second common intermediate layer COM2 may be disposed over the entire display area DA while being located between the light emitting layers EML1 and EML2 and the cathode CAT.

Referring to FIG. 21, in the display area DA, the light emitting areas of the light emitting elements ED1 and ED2 may be defined by openings of a bank BK. The bank BK may be located on the anodes AND1 and AND2, and may have the openings which expose portions of the anodes AND1 and AND2. The openings of the bank BK may be light emitting areas. The bank BK may also be referred to as a light emitting part defining layer.

Referring to FIG. 21, the display panel 110 according to the aspects of the present disclosure may include a connection metal structure for connection between the base circuit layer 1710 and the light emitting element layer EDL.

Referring to FIG. 21, the connection metal structure of the display panel 110 according to the aspects of the present disclosure may include a first metal layer disposed between the first insulating layer INS1 and the second insulating layer INS2, a second metal layer disposed between the second insulating layer INS2 and the third insulating layer INS3, and a third metal layer disposed between the third insulating layer INS3 and the light emitting element layer EDL.

Referring to FIG. 21, the display panel 110 according to the aspects of the present disclosure may include a second anode connection structure for electrically connecting the second anode AND2 disposed in the light emitting element layer EDL and the second subpixel circuit SPC2 disposed in the base circuit layer 1710 on a one-to-one basis.

Referring to FIG. 21, the second anode connection structure of the display panel 110 according to the aspects of the present disclosure may include a second anode connection pattern CP_AND2. Each of the at least two second anodes AND2 may be electrically connected to the second subpixel circuit SPC2 disposed in the base circuit layer 1710 through the second anode connection pattern CP_AND2.

Referring to FIG. 21, the second anode connection pattern CP_AND2 may include a second metal connection pattern CP2_AND2 and a first metal connection pattern CP1_AND2.

Referring to FIG. 21, the at least two second anodes AND2 may be disposed in the third metal layer. One second anode AND2 may be electrically connected to the second metal connection pattern CP2_AND2 located in the second metal layer through a hole of the third insulating layer INS3, the second metal connection pattern CP2_AND2 may be electrically connected to the first metal connection pattern CP1_AND2 located in the first metal layer through a hole of the second insulating layer INS2, and the first metal connection pattern CP1_AND2 may be electrically connected to the second subpixel circuit SPC2 disposed in the base circuit layer 1710 through a hole of the first insulating layer INS1.

Referring to FIG. 21, the at least two first anodes AND1 may be electrically connected to the first subpixel circuit SPC1 disposed in the base circuit layer 1710, through an anode extension link AEL disposed in an anode extension link layer 1730.

Referring to FIG. 21, the display panel 110 according to the aspects of the present disclosure may include a first anode connection structure for electrically connecting the at least two first anodes AND1 disposed in the light emitting element layer EDL and the first subpixel circuit SPC1 disposed in the base circuit layer 1710.

Referring to FIG. 21, the first anode connection structure of the display panel 110 according to the aspects of the present disclosure may include the anode extension link AEL and an anode connection pattern CP1_AND1.

Referring to FIG. 21, the at least two first anodes AND1 may be disposed in the third metal layer. The anode extension link layer 1730 may be the second metal layer on the second insulating layer INS2. The anode connection pattern CP1_AND1 may include a first metal connection pattern CP1_AND1 located in the first metal layer on the first insulating layer INS1.

Referring to FIG. 21, in the first display area DA1, each of the at least two first anodes AND1 may be electrically connected to one anode extension link AEL located in the second metal layer, through a hole of the third insulating layer INS3. The second metal layer may be the anode extension link layer 1730.

Referring to FIG. 21, the anode extension link AEL may be electrically connected to the first metal connection pattern CP1_AND1 located in the first metal layer through a hole of the second insulating layer INS2, and the first metal connection pattern CP1_AND1 may be electrically connected to the first subpixel circuit SPC1 disposed in the base circuit layer 1710 through a hole of the first insulating layer INS1.

Referring to FIG. 21, the anode extension link AEL may include a first part which is electrically connected to the at least two first anodes AND1 located in the light emitting element layer EDL in the first display area DA1, and a second part which is connected to the first subpixel circuit SPC1 located in the base circuit layer 1710 in the second display area DA2. The first part may be located in the first display area DA1, and the second part may be located in the second display area DA2.

Referring to FIG. 21, the anode extension link AEL may be disposed to extend from the first display area DA1 to the second display area DA2 when viewed in a plan view. The first anode connection structure including the anode extension link AEL may be located from the base circuit layer 1710 to the light emitting element layer EDL in a vertical direction.

Referring to FIG. 21, in the base circuit layer 1710, the link area LKA may be located between the subpixel circuit array SPCA and the gate-in-panel circuit GIPC.

Referring to FIG. 21, a shielding layer 1720 may be located between the gate-in-panel circuit GIPC included in the base circuit layer 1710 and the light emitting element layer EDL.

The shielding layer 1720 may be disposed in the first display area DA1.

The shielding layer 1720 may be electrically connected to a cathode connection pattern CP_VSS. Accordingly, the base voltage VSS to be applied to the cathode CAT of the light emitting elements ED1 and ED2 may be applied to the shielding layer 1720.

The shielding layer 1720 may be disposed in the first display area DA1, and may be located between the gate-in-panel circuit GIPC and the anode extension link AEL. The shielding layer 1720 may overlap the gate-in-panel circuit GIPC, and may overlap the anode extension link AEL.

Accordingly, the anode extension link AEL may not be electrically affected by the gate-in-panel circuit GIPC. The gate-in-panel circuit GIPC may not be electrically affected by the anode extension link AEL.

Referring to FIG. 21, the display panel 110 according to the aspects of the present disclosure may include the substrate 111 including the display area DA including the first display area DA1 and the second display area DA2 and the non-display area NDA outside the display area DA, the at least two first light emitting elements ED1 disposed in the first display area DA1, the at least two second light emitting elements ED2 disposed in the second display area DA2, the one first subpixel circuit SPC1 connected in common to the at least two first light emitting elements ED1, and the at least two second subpixel circuits SPC2 respectively connected to the at least two second light emitting elements ED2.

Referring to FIG. 21, the display panel 110 according to the aspects of the present disclosure may further include the gate-in-panel circuit GIPC disposed in the first display area DA1.

Referring to FIG. 21, the display panel 110 according to the aspects of the present disclosure may further include the anode extension link AEL for electrically connecting the at least two first light emitting elements ED1 and the one first subpixel circuit SPC1.

Referring to FIG. 21, the display panel 110 according to the aspects of the present disclosure may further include the shielding layer 1720 disposed between the gate-in-panel circuit GIPC and the anode extension link AEL.

Referring to FIG. 21, in the display panel 110 according to the aspects of the present disclosure, a base voltage line VSSL may be disposed in the display area DA. For example, the base voltage line VSSL may be disposed in at least one of the first display area DA1 and the second display area DA2 included in the display area DA. Accordingly, the cathode CAT may be electrically connected to the base voltage line VSSL in at least one of the first display area DA1 and the second display area DA2 included in the display area DA.

Accordingly, a base voltage line area VSSA may not exist in the non-display area NDA. Due to this fact, a bezel, which is the non-display area NDA, may become smaller.

Referring to FIG. 21, in the display panel 110 according to the aspects of the present disclosure, the base voltage line VSSL may be located in the display area DA. The display panel 110 according to the aspects of the present disclosure may include a cathode connection structure for electrically connecting the cathode CAT and the base voltage line VSSL, and the cathode connection structure may be located in the display area DA.

For example, the base voltage line VSSL may be disposed in at least one of the first display area DA1 and the second display area DA2 included in the display area DA. Accordingly, the cathode CAT may be electrically connected to the base voltage line VSSL through the cathode connection structure located in at least one of the first display area DA1 and the second display area DA2 included in the display area DA.

Referring to FIG. 21, the cathode connection pattern CP_VSS, which is the cathode connection structure for connecting the cathode CAT and the base voltage line VSSL, may be located in the display area DA. That is to say, the cathode connection pattern CP_VSS may be located in at least one of the first display area DA1 and the second display area DA2 included in the display area DA.

Referring to FIG. 21, the cathode CAT may be electrically connected to the cathode connection pattern CP_VSS located below the bank BK, through a hole of the bank BK located between at least two second anodes AND2.

Referring to FIG. 21, the base voltage line VSSL may be located in the first metal layer on the first insulating layer INS1. The cathode connection pattern CP_VSS may include a first cathode connection pattern CP2_VSS located in the second metal layer on the second insulating layer INS2.

The cathode CAT may be electrically connected to the first cathode connection pattern CP2_VSS through holes of the second common intermediate layer COM2, the first common intermediate layer COM1, the bank BK and the third insulating layer INS3.

The first cathode connection pattern CP2_VSS may be electrically connected to the base voltage line VSSL located on the first insulating layer INS1, through a hole of the second insulating layer INS2.

Referring to FIG. 21, the through holes of the second common intermediate layer COM2, the first common intermediate layer COM1, the bank BK and the third insulating layer INS3 may be formed through a laser drilling process.

According to the above description, the base voltage line VSSL and the cathode connection pattern CP_VSS, which is the cathode connection structure, do not need to be disposed in the non-display area NDA. Accordingly, the bezel may be further reduced to the extreme.

The display panel 110 according to the aspects of the present disclosure may include the three insulating layers INS1 to INS3 and the three metal layers between the base circuit layer 1710 and the light emitting element layer EDL, as a connection metal structure for connection between the base circuit layer 1710 and the light emitting element layer EDL. The three insulating layers INS1 to INS3 may be included in the insulating layer stack INS. The three metal layers may include the first metal layer disposed between the first insulating layer INS and the second insulating layer INS2, the second metal layer disposed between the second insulating layer INS2 and the third insulating layer INS3, and the third metal layer disposed between the third insulating layer INS3 and the light emitting element layer EDL. The third metal layer may be a metal layer in which the anodes AND1 and AND2 are disposed.

The display panel 110 according to the aspects of the present disclosure may have a connection metal structure different from the connection metal structure (three insulating layers and three metal layers) between the base circuit layer 1710 and the light emitting element layer EDL.

Referring to FIG. 21, a voltage having a predetermined voltage level may be applied to the shielding layer 1720.

Referring to FIG. 21, the display panel 110 may further include the base voltage line VSSL which is disposed on the substrate 111 and is a second common driving voltage line for supplying the base voltage VSS being a second common pixel driving voltage to the cathode CAT. The base voltage line VSSL, which is the second common driving voltage line, may be disposed in the display area DA. The cathode CAT may be electrically connected to the base voltage line VSSL which is the second common driving voltage line, in the display area DA.

The bank BK may be located on the insulating layer stack INS, and may have a first opening and a second opening.

The first anode AND1 and the second anode AND2 may be located on the insulating layer stack INS, and may overlap the first opening and the second opening, respectively.

The first common intermediate layer COM1 may be disposed in common on the first anode AND1 and the second anode AND2.

The first light emitting layer EML1 and the second light emitting layer EML2 may be located on the first common intermediate layer COM1, and may overlap the first anode AND1 and the second anode AND2.

The second common intermediate layer COM2 may be disposed in common on the first light emitting layer EML1 and the second light emitting layer EML2.

The first common intermediate layer COM1 and the second common intermediate layer COM2 may be collectively referred to as a common intermediate layer EL_COM.

The cathode CAT may be located on the common intermediate layer EL_COM.

Through holes penetrating at least portions of the second common intermediate layer COM2, the first common intermediate layer COM1, the bank BK and the insulating layer stack INS, the cathode CAT and the second base voltage line VSSL which is the second common driving voltage line may be electrically connected.

The first anode AND1, the first common intermediate layer COM1, the first light emitting layer EML1, the second common intermediate layer COM2 and the cathode CAT may overlap to constitute the first light emitting element ED1.

The second anode AND2, the first common intermediate layer COM1, the second light emitting layer EML2, the second common intermediate layer COM2 and the cathode CAT may overlap to constitute the second light emitting element ED2.

In FIGS. 17 to 21, one of the plurality of first light emitting elements ED1 disposed in the first display area DA1 may be an outermost light emitting element ED.

Referring to FIG. 21, a stopper STP may be disposed on the outer side surface of the first light emitting element ED1 which is the outermost light emitting element ED. The stopper STP and its surrounding structure may be the same as in FIG. 5.

Referring to FIG. 21, the stopper STP may be disposed outside an organic layer PCL of an encapsulation layer 200. The stopper STP may be disposed outside the bank BK.

Referring to FIG. 21, at least a portion of the stopper STP may overlap at least a portion of the gate-in-panel circuit GIPC disposed on the base circuit layer 1710.

A brief description of the aspects of the present disclosure described above is as follows.

A display device according to aspects of the present disclosure may include a substrate including a display area in which a plurality of subpixels are disposed and a non-display area which includes a pad area located in a first direction from the display area; an insulating layer stack located on the substrate, and having an outer side surface in the non-display area; a stopper located on the insulating layer stack; a cathode located on the insulating layer stack, and extending from the display area to a part of the non-display area to overlap at least a portion of a top surface of the stopper; a first inorganic layer located on the cathode, and disposed to extend from the display area to the non-display area; an organic layer located on a part of the first inorganic layer, and having an outer sloped surface; and a second inorganic layer located on the organic layer, disposed to extend from the display area to the non-display area, and disposed to extend along the outer sloped surface of the organic layer.

In the display device according to the aspects of the present disclosure, the stopper may be disposed in the non-display area and may be located outside the organic layer.

The display device according to the aspects of the present disclosure may further include a bank located on the insulating layer stack and having a plurality of openings, a plurality of anodes located on the insulating layer stack and overlapping the plurality of openings, and a plurality of light emitting layers located on the plurality of anodes.

The cathode may be located on the plurality of light emitting layers, and a plurality of light emitting elements may be configured as the plurality of anodes, the plurality of light emitting layers and the cathode overlap. The stopper may be disposed outside the bank.

The first inorganic layer may extend along a top and an outside of the stopper to the outer side surface of the insulating layer stack.

The second inorganic layer may extend to an outside of the outer sloped surface of the organic layer, and may be located on the first inorganic layer which extends along the top and the outside of the stopper to the outer side surface of the insulating layer stack.

An outer side surface of the stopper may have a steeper slope than an inner side surface of the stopper.

The display device according to the aspects of the present disclosure may further include a bank located on the insulating layer stack, and having first to third openings; first to third anodes located on the insulating layer stack, and overlapping the first to third openings, respectively; a first common intermediate layer disposed in common on the first to third anodes; first to third light emitting layers located on the first common intermediate layer, and overlapping the first to third anodes; and a second common intermediate layer disposed in common on the first to third light emitting layers.

A common intermediate layer including the first common intermediate layer and the second common intermediate layer may include an organic material, the cathode may be located on the second common intermediate layer, and the common intermediate layer and the cathode may extend to the top of the stopper.

The display device according to the aspects of the present disclosure may further include a capping layer located between the cathode and the first inorganic layer, and disposed to extend from the display area to the non-display area. The capping layer may extend along the top and the outside of the stopper to the outer side surface of the insulating layer stack.

The stopper may include a first stopper on the insulating layer stack; and a second stopper on the first stopper. The first stopper may include the same material as the bank, and the second stopper may include the same material as a spacer located on the bank.

An end of the common intermediate layer and an end of the cathode may be located on the stopper, and the end of the cathode may protrude further outward than an upper layer part of the outer side surface of the stopper (e.g., an outer side surface of the second stopper) and the end of the common intermediate layer.

A lower end portion of an outer side surface of the first stopper may protrude further outward than an upper end portion of an outer side surface of the second stopper.

The stopper may include a cliff portion from the top to a point where the slope of the outer side surface is gentle below a predetermined level or to a point where there is a step. A value obtained by summing a height of the cliff portion of the stopper and a height of the common intermediate layer may be larger than a sum of a thickness of the first inorganic layer and a thickness of the second inorganic layer.

The stopper may be disposed on a side surface of an outermost light emitting element among a plurality of light emitting elements corresponding to the plurality of subpixels. The stopper may have a thickness thicker than an anode of the outermost light emitting element.

A width of a bottom surface of the stopper may be larger than a width of the top surface of the stopper.

The display device according to the aspects of the present disclosure may further include a display signal line disposed in the display area; a display connecting line electrically connecting the display signal line and a display pad disposed in the pad area; and a bending organic layer located between the display area and the pad area.

A portion of the display connecting line may overlap the bending organic layer.

The non-display area may include a first non-display area located in the first direction from the display area; a second non-display area located in a second direction from the display area; a third non-display area located in a direction opposite to the first direction from the display area; and a fourth non-display area located in a direction opposite to the second direction from the display area. The pad area may be included in the first non-display area.

The stopper may be disposed in the non-display area, and may be disposed in the shape of a ring which surrounds a periphery of the organic layer. The stopper is located between the display area and the pad area.

The display device according to the aspects of the present disclosure may further include a first sensor electrode disposed on the second inorganic layer, and extending in the second direction; and a first touch routing line for electrically connecting the first sensor electrode to a first touch pad disposed in the pad area.

The first touch routing line may extend to the first non-display area by traversing the display area in the first direction, without bypassing the second non-display area and the fourth non-display area.

A portion of the first touch routing line extending to the first non-display area may overlap the stopper in the first non-display area.

The display device according to the aspects of the present disclosure may further include a gate-in-panel circuit configured to supply a gate signal to the plurality of subpixels. The gate-in-panel circuit may be disposed on the substrate, and may overlap the organic layer.

The display device according to the aspects of the present disclosure may further include a base circuit layer on the substrate; a light emitting element layer located on the base circuit layer, and including a plurality of light emitting elements included in the plurality of subpixels; and a shielding layer located between the base circuit layer and the light emitting element layer.

The base circuit layer may include the gate-in-panel circuit disposed in the display area.

A voltage with a predetermined voltage level may be applied to the shielding layer.

The display device according to the aspects of the present disclosure may further include a common driving voltage line disposed on the substrate to supply a common pixel driving voltage to the cathode. The common driving voltage line may be disposed in the display area, and the cathode may be electrically connected to the common driving voltage line in the display area.

The display device according to the aspects of the present disclosure may further include a subpixel circuit layer located between the shielding layer and the light emitting element layer, and including a plurality of subpixel circuits for driving a plurality of light emitting elements; and a gate link line connecting the gate-in-panel circuit disposed in the base circuit layer and the plurality of subpixel circuits.

The gate link line may overlap the organic layer.

The display area may include a first display area and a second display area.

The base circuit layer may further include, in addition to the gate-in-panel circuit, a subpixel circuit array including a plurality of subpixel circuits for driving the plurality of light emitting elements.

The gate-in-panel circuit may be disposed in the first display area, and the subpixel circuit array may be disposed in the second display area.

The plurality of light emitting elements may include a first light emitting element disposed in the first display area, and overlapping at least a portion of the gate-in-panel circuit; and a second light emitting element disposed in the second display area, and overlapping at least a portion of the subpixel circuit array.

The plurality of subpixel circuits may include a first subpixel circuit configured to drive the first light emitting element, and disposed in the second display area; and at least two second subpixel circuits configured to drive the second light emitting element, and disposed in the second display area.

The display device according to the aspects of the present disclosure may further include an extension link connecting the first subpixel circuit disposed in the second display area to the first light emitting element disposed in the first display area.

At least a portion of the extension link may overlap at least a portion of the gate-in panel circuit. The extension link may overlap the organic layer.

A display device according to aspects of the present disclosure may include a substrate; an insulating layer stack on the substrate; a plurality of light emitting elements on the insulating layer stack; an organic layer on the plurality of light emitting elements; and a stopper disposed outside the organic layer.

The stopper may be disposed on an outer side surface of an outermost light emitting element among the plurality of light emitting elements. The stopper may have a thickness thicker than an anode of the outermost light emitting element.

The display device according to the aspects of the present disclosure may further include a bank for dividing the plurality of light emitting elements; and a spacer on the bank.

The stopper may include a first stopper on the insulating layer stack and a second stopper on the first stopper. The first stopper may include the same material as the bank, and the second stopper may include the same material as the spacer.

An outer side surface of the stopper may have a steeper slope than an inner side surface of the stopper.

According to the aspects of the present disclosure described above, it is possible to provide a display device having an extremely narrow bezel structure.

According to the aspects of the present disclosure, it is possible to provide a display device having an organic layer overflow prevention structure which enables an extremely narrow bezel.

According to the aspects of the present disclosure, it is possible to provide a display device including a gate-in-panel circuit structure which enables an extremely narrow bezel.

According to the aspects of the present disclosure, it is possible to provide a display device having a touch routing structure which enables an extremely narrow bezel.

According to the aspects of the present disclosure, by having an extremely narrow bezel structure, it is possible to achieve light weight of a display device.

The above description has been presented to enable any person skilled in the art to make and use the technical idea of the present disclosure, and has been provided in the context of a particular application and its requirements. Various modifications, additions and substitutions to the described aspects will be readily apparent to those skilled in the art, and the general principles defined herein may be applied to other aspects and applications without departing from the spirit and scope of the present disclosure. Thus, it is intended that the present disclosure covers the modifications and variations of the aspects provided they come within the scope of the appended claims and their equivalents.

What is claimed is:

1. A display device comprising:
a substrate including a display area in which a plurality of subpixels are disposed and a non-display area which includes a pad area located in a first direction from the display area;
an insulating layer stack located on the substrate, and having an outer side surface in the non-display area;
a stopper located on the insulating layer stack;
a cathode located on the insulating layer stack, and extending from the display area to a part of the non-display area to overlap at least a portion of a top surface of the stopper;
a first inorganic layer located on the cathode, and disposed to extend from the display area to the non-display area;
an organic layer located on a part of the first inorganic layer, and having an outer sloped surface; and
a second inorganic layer located on the organic layer, disposed to extend from the display area to the non-display area, and disposed to extend along the outer sloped surface of the organic layer,
wherein the stopper is disposed in the non-display area and is located outside the organic layer.

2. The display device of claim 1, further comprising a bank located on the insulating layer stack to divide a plurality of light emitting areas,
wherein the stopper is disposed outside the bank.

3. The display device of claim 1, wherein the first inorganic layer extends along a top and an outside of the stopper to the outer side surface of the insulating layer stack, and
wherein the second inorganic layer extends to an outside of the outer sloped surface of the organic layer, and is located on the first inorganic layer which extends along the top and the outside of the stopper to the outer side surface of the insulating layer stack.

4. The display device of claim 1, wherein an outer side surface of the stopper has a slope steeper than an inner side surface of the stopper.

5. The display device of claim 1, further comprising:
a bank located on the insulating layer stack, and having first to third openings;
first to third anodes located on the insulating layer stack, and overlapping the first to third openings, respectively;
a first common intermediate layer disposed in common on the first to third anodes;
first to third light emitting layers located on the first common intermediate layer, and overlapping the first to third anodes; and
a second common intermediate layer disposed in common on the first to third light emitting layers,
wherein a common intermediate layer including the first common intermediate layer and the second common intermediate layer includes an organic material,
wherein the cathode is located on the second common intermediate layer, and
wherein the common intermediate layer and the cathode extend to the top of the stopper.

6. The display device of claim 5, further comprising a capping layer located between the cathode and the first inorganic layer, and disposed to extend from the display area to the non-display area,
wherein the capping layer extends along the top and the outside of the stopper to the outer side surface of the insulating layer stack.

7. The display device of claim 5, wherein an end of the common intermediate layer and an end of the cathode are located on the stopper, and
wherein the end of the cathode protrudes further outward than an upper layer part of the outer side surface of the stopper and the end of the common intermediate layer.

8. The display device of claim 5, wherein the stopper includes a cliff portion from the top to a point where the slope of the outer side surface is gentle below a predetermined level or to a point where there is a step, and
wherein a value obtained by summing a height of the cliff portion of the stopper and a height of the common intermediate layer is larger than a sum of a thickness of the first inorganic layer and a thickness of the second inorganic layer.

9. The display device of claim 5, wherein the stopper comprises:
a first stopper disposed on the insulating layer stack; and
a second stopper disposed on the first stopper,
wherein the first stopper includes a same material as the bank, and
wherein the second stopper includes a same material as a spacer located on the bank.

10. The display device of claim 9, wherein a lower end portion of an outer side surface of the first stopper protrudes further outward than an upper end portion of an outer side surface of the second stopper.

11. The display device of claim 1, wherein the stopper is disposed on a side surface of an outermost light emitting element among a plurality of light emitting elements corresponding to the plurality of subpixels, and has a thickness thicker than an anode of the outermost light emitting element.

12. The display device of claim 1, wherein a width of a bottom surface of the stopper is larger than a width of the top surface of the stopper.

13. The display device of claim 1, further comprising:
a display signal line disposed in the display area;
a display connecting line electrically connecting the display signal line and a display pad disposed in the pad area; and
a bending organic layer located between the display area and the pad area,
wherein a portion of the display connecting line overlaps the bending organic layer.

14. The display device of claim 1, wherein the non-display area comprises:
a first non-display area located in the first direction from the display area;
a second non-display area located in a second direction from the display area;
a third non-display area located in a direction opposite to the first direction from the display area; and
a fourth non-display area located in a direction opposite to the second direction from the display area,
wherein the pad area is included in the first non-display area, and
wherein the stopper is disposed in the shape of a ring which is disposed in the non-display area and surrounds a periphery of the organic layer, and the stopper is located between the display area and the pad area.

15. The display device of claim 14, further comprising:
a first sensor electrode disposed on the second inorganic layer, and extending in the second direction; and
a first touch routing line for electrically connecting the first sensor electrode to a first touch pad disposed in the pad area,
wherein the first touch routing line extends to the first non-display area by traversing the display area in the first direction, without bypassing the second non-display area and the fourth non-display area, and
wherein a portion of the first touch routing line extending to the first non-display area overlaps the stopper in the first non-display area.

16. The display device of claim 1, further comprising a gate-in-panel circuit configured to supply a gate signal to the plurality of subpixels,
wherein the gate-in-panel circuit is disposed on the substrate and overlaps the organic layer.

17. The display device of claim 16, further comprising:
a base circuit layer disposed on the substrate;
a light emitting element layer located on the base circuit layer, and including a plurality of light emitting elements included in the plurality of subpixels; and
a shielding layer located between the base circuit layer and the light emitting element layer,
wherein the base circuit layer includes the gate-in-panel circuit disposed in the display area.

18. The display device of claim 17, wherein a voltage with a predetermined voltage level is applied to the shielding layer.

19. The display device of claim 17, further comprising a common driving voltage line disposed on the substrate to supply a common pixel driving voltage to the cathode,
wherein the common driving voltage line is disposed in the display area, and the cathode is electrically connected to the common driving voltage line in the display area.

20. The display device of claim 17, further comprising:
a subpixel circuit layer located between the shielding layer and the light emitting element layer, and including a plurality of subpixel circuits for driving a plurality of light emitting elements; and
a gate link line connecting the gate-in-panel circuit disposed in the base circuit layer and the plurality of subpixel circuits,
wherein the gate link line overlaps the organic layer.

21. The display device of claim 17, wherein the display area includes a first display area and a second display area,
wherein the base circuit layer further includes, in addition to the gate-in-panel circuit, a subpixel circuit array including a plurality of subpixel circuits for driving the plurality of light emitting elements,
wherein the gate-in-panel circuit is disposed in the first display area,
wherein the subpixel circuit array is disposed in the second display area,
wherein the plurality of light emitting elements comprise:
a first light emitting element disposed in the first display area, and overlapping at least a portion of the gate-in-panel circuit; and
a second light emitting element disposed in the second display area, and overlapping at least a portion of the subpixel circuit array, and
wherein the plurality of subpixel circuits comprise:
a first subpixel circuit configured to drive the first light emitting element, and disposed in the second display area; and
at least two second subpixel circuits configured to drive the second light emitting element, and disposed in the second display area.

22. The display device of claim 21, further comprising an extension link connecting the first subpixel circuit disposed in the second display area to the first light emitting element disposed in the first display area,
wherein at least a portion of the extension link overlaps at least a portion of the gate-in panel circuit, and the extension link overlaps the organic layer.

23. The display device of claim 21, further comprising:
a base voltage line, located in at least one of the first display area and the second display area; and
a cathode connection pattern, connecting the cathode and the base voltage and located in at least one of the first display area and the second display area.

24. The display device of claim 1, further comprising a patterning organic material disposed outside the stopper.

25. A display device comprising:
a substrate;
an insulating layer stack on the substrate;
a plurality of light emitting elements on the insulating layer stack;
an organic layer on the plurality of light emitting elements; and
a stopper disposed outside the organic layer,
wherein the stopper is disposed on an outer side surface of an outermost light emitting element among the plurality of light emitting elements, and has a thickness thicker than an anode of the outermost light emitting element.

26. The display device of claim 25, further comprising:
a bank for dividing the plurality of light emitting elements; and
a spacer disposed on the bank,
wherein the stopper includes a first stopper on the insulating layer stack and a second stopper on the first stopper,
wherein the first stopper includes a same material as the bank, and
wherein the second stopper includes a same material as the spacer.

27. The display device of claim 25, wherein an outer side surface of the stopper has a slope steeper than an inner side surface of the stopper.
